(19) United States
(12) Patent Application Publication
(10) Pub. No.: US 2024/0057416 A1
(43) Pub. Date: Feb. 15, 2024

(54) DISPLAY APPARATUS HAVING A LIGHT-EMITTING DEVICE

(71) Applicant: LG Display Co., Ltd., Seoul (KR)

(72) Inventors: Geon Do PARK, Paju-si (KR); Seol HEO, Paju-si (KR); Seon Woo LEE, Paju-si (KR); Oh Sung KWON, Paju-si (KR)

(21) Appl. No.: 18/448,823

(22) Filed: Aug. 11, 2023

(30) Foreign Application Priority Data
Aug. 12, 2022 (KR) 10-2022-0101309

(51) Int. Cl. H10K 59/131

(52) U.S. Cl. CPC H10K 59/131

(57) ABSTRACT

A display apparatus including a light-emitting device is provided. The light-emitting device may be disposed in an emission area of a pixel area. The light-emitting device may be electrically connected to a driving circuit. The driving circuit may be disposed outside the light-emitting device. The driving circuit may be electrically connected to a signal wiring by a connection wiring. The connection wiring may include a transparent wiring region overlapping with the emission area and an opaque wiring region disposed outside the emission area. The transparent wiring region may have a transmittance higher than the opaque wiring region. Thus, in the display apparatus, a decrease in luminous efficiency may be prevented.

### CROSS-REFERENCE TO RELATED APPLICATIONS

This application claims the benefit of Korean Patent Application No. 10-2022-0101309, filed on Aug. 12, 2022, which is hereby incorporated by reference as if fully set forth herein.

### BACKGROUND

### Technical Field

The present disclosure relates to a display apparatus in which a light-emitting device and a driving circuit are disposed in a pixel area.

### Description of the Related Art

Generally, a display apparatus provides an image to user. For example, the display apparatus may include a light-emitting device in each pixel area of a device substrate. The light-emitting device may emit light displaying a specific color. For example, the light-emitting device may include a first electrode, a light-emitting layer and a second electrode, which are sequentially stacked on the device substrate.

A driving circuit electrically connected to the light-emitting device may be disposed in each pixel area. The driving circuit may provide a driving current corresponding to a data signal to the light-emitting device according to a gate signal. The gate signal and the data signal may be applied to the driving circuit of each pixel area by signal wirings. For example, the driving circuit of each pixel area may be electrically connected to one of gate lines applying the gate signal and one of data lines applying the data signal.

Light generated by the light-emitting device of each pixel area may be emitted outside through the device substrate. For example, the driving circuit of each pixel area may not overlap the light-emitting device of the corresponding pixel area. Thus, in the display apparatus, the light emitted from the light-emitting device of each pixel area may be not blocked by the driving circuit of the corresponding pixel area.

The signal wirings may be disposed outside the pixel areas. For example, each of the pixel areas may be defined by the signal wirings. Each of the signal wirings may extend in a direction. For example, the data lines may extend in a first direction, and the gate lines may extend in a second direction perpendicular to the first direction. The driving circuit of each pixel area may be electrically connected to the signal wirings through connection wirings.

### BRIEF SUMMARY

The inventors recognized that the connection wirings may be cut by a repair process. For example, the connection wirings may be formed as an opaque conductive layer, which can be melted/cut by laser irradiation. Thus, in the display apparatus, the light emitted from the light-emitting device of each pixel area may be blocked by the connection wirings. That is, in the display apparatus, an area of the emission area of each pixel area may be reduced due to the connection wirings. Therefore, in the display apparatus, luminous efficiency of each pixel area may be decreased.

The present disclosure is directed to a display apparatus that substantially obviates one or more problems due to limitations and disadvantages of the related art.

The present disclosure provides a display apparatus capable of improving luminous efficiency of each pixel area, without affecting a repair process.

The present disclosure provides a display apparatus capable of preventing an area reduction of an emission area in each pixel area due to connection wirings, without a decrease in process efficiency.

Additional improvements, technical benefits, and features of the disclosure will be set forth in part in the description which follows and in part will become apparent to those having ordinary skill in the art upon examination of the following or may be learned from practice of the disclosure. The technical benefits and other features of the disclosure may be realized and attained by the structure particularly pointed out in the written description and claims hereof as well as the appended drawings.

To achieve these technical benefits and other features and in accordance with the present disclosure, as embodied and broadly described herein, there is provided a display apparatus comprising a device substrate. A light-emitting device is disposed on an emission area of the device substrate. The light-emitting device is electrically connected to a driving circuit. The driving circuit is disposed outside the light-emitting device. A signal wiring is disposed outside the light-emitting device and the driving circuit. The signal wiring extends in a direction. The driving circuit is electrically connected to the signal wiring by a connection wiring. The connection wiring includes a first wiring region and a second wiring region. The second wiring region has a transmittance higher than the first wiring region. The second wiring region overlaps the emission area.

A color filter may be disposed between the second wiring region of the connection wiring and the light-emitting device.

The first wiring region may have a resistance lower than the second wiring region.

A thickness of the second wiring region may be smaller than a thickness of the first wiring region.

The first wiring region may include a lower wiring layer and an upper wiring layer. The upper wiring layer may be disposed on the lower wiring layer. A resistance of the upper wiring layer may be lower than a resistance of the lower wiring layer. The second wiring region may include a same material as the lower wiring layer.

The upper wiring layer may include a metal.

The second wiring region may have a resistance lower than the lower wiring layer.

The lower wiring layer may be a region of an oxide semiconductor, which is not conductorized. The second wiring region may be a conductorized region of an oxide semiconductor.

In an embodiment, there is provided a display apparatus comprising a device substrate. A bank insulating layer is disposed on the device substrate. The bank insulating layer is adjacent to, surrounds, or defines an emission area in a pixel area. A light-emitting device is disposed on the emission area of the device substrate. The light-emitting device includes a first electrode, a light-emitting layer and a second electrode, which are sequentially stacked. A driving circuit is disposed between the pixel area of the device substrate and the bank insulating layer. The driving circuit includes at least one thin film transistor. A signal wiring is disposed outside the pixel area. The signal wiring is electrically connected to the driving circuit by a connection wiring. The connection wiring includes a transparent wiring region overlapping with the first electrode of the light-emitting device. A transmittance of the transparent wiring region is higher than a transmittance of the signal wiring.

An intermediate insulating layer may be disposed on the connection wiring and the signal wiring. An intermediate electrode may be disposed on the intermediate insulating layer. The transparent wiring region of the connection wiring may be electrically connected to the signal wiring by the intermediate electrode. The intermediate electrode may partially cover an upper surface of the transparent wiring region opposite to the device substrate.

The transparent wiring region of the connection wiring may include a same material as a semiconductor pattern of the thin film transistor.

The transparent wiring region of the connection wiring may have a same resistance as a source region and a drain region of the semiconductor pattern.

A source electrode and a drain electrode of the thin film transistor may include a lower conductive layer and an upper conductive layer, respectively. The upper conductive layer may be disposed on the lower conductive layer. A resistance of the upper conductive layer may be lower than a resistance of the lower conductive layer. The lower conductive layer may include a same material as the semiconductor pattern.

The lower conductive layer may have a same resistance as a channel region of the semiconductor pattern.

The upper conductive layer may include a material different from a gate electrode of the thin film transistor.

### BRIEF DESCRIPTION OF THE SEVERAL VIEWS OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is a view showing a circuit of each pixel area in the display apparatus according to the embodiment of the present disclosure;

FIG. 3 is an enlarged view of a portion in the display apparatus according to the embodiment of the present disclosure;

FIG. 4 is an enlarged view of K1 in FIG. 3;

FIG. 5 is a view taken along I-I′ of FIG. 3;

FIG. 6 is a view taken along II-IP of FIG. 3;

FIG. 7 is a view taken along III-III′ of FIG. 4;

FIG. 8 is a view taken along IV-IV′ of FIG. 4;

FIGS. 9 to 22 are views sequentially showing a method of forming the display apparatus according to the embodiment of the present disclosure;

FIG. 23 is an enlarged view of a portion in the display apparatus according to an embodiment of the present disclosure;

FIG. 24 is an enlarged view of K2 in FIG. 23;

FIG. 25 is a view taken along V-V′ of FIG. 24;

FIG. 26 is a view taken along VI-VI′ of FIG. 24;

FIGS. 27 to 34 are views sequentially showing a method of forming the display apparatus according to an embodiment of the present disclosure; and

FIG. 35 is a view showing the display apparatus according to further an embodiment of the present disclosure.

### DETAILED DESCRIPTION

Hereinafter, details related to the technical benefits, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure may be embodied in other forms and is not limited to the embodiments described below.

In addition, the same or extremely similar elements may be designated by the same reference numerals throughout the specification and in the drawings, the lengths and thickness of layers and regions may be exaggerated for convenience. It will be understood that, when a first element is referred to as being “on” a second element, although the first element may be disposed on the second element so as to come into contact with the second element, a third element may be interposed between the first element and the second element.

Here, terms such as, for example, “first” and “second” may be used to distinguish any one element with another element. However, the first element and the second element may be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” may include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiment

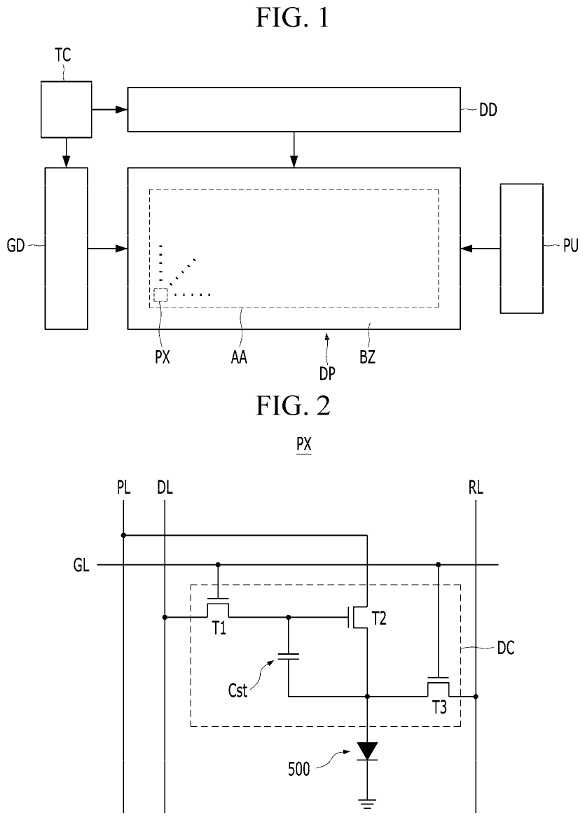

FIG. 1 is a view schematically showing a display apparatus according to an embodiment of the present disclosure. FIG. 2 is a view showing a circuit of each pixel area in the display apparatus according to the embodiment of the present disclosure.

Referring to FIGS. 1 and 2, the display apparatus according to the embodiment of the present disclosure may include a display panel DP. The display panel DP may generate an image provided to a user. For example, the display panel DP may include a plurality of pixel area PX.

The display panel DP may be electrically connected to a data driver DD, a gate driver GD and a power unit PU by signal wirings DL, GL, PL and RL. The signal wirings GL, DL, PL and RL may include data lines DL, gate lines GL, power voltage supply lines PL and reference voltage supply lines RL. The data driver DD may apply a data signal to each pixel area PX of the display panel DP through the data lines DL, and the gate driver GD may sequentially apply a gate signal to each pixel area PX of the display panel DP through the gate lines GL. The power unit PU may supply a power voltage to each pixel area PX of the display panel DP through the power voltage supply lines PL and may supply a reference voltage to each pixel area PX of the display panel DP through the reference voltage supply lines RL.

Each of the signal wirings DL, GL, PL and RL may extend in a direction. For example, the data lines DL, the power voltage supply lines PL and the reference voltage supply lines RL may extend in a first direction. The pixel areas PX of the display panel DP may be connected to the signal wirings DL, GL, PL and RL. For example, the gate lines GL may extend in a second direction perpendicular to the first direction. Each of the gate lines GL may intersect the data lines DL, the power voltage supply lines PL and the reference voltage supply lines RL. For example, the pixel areas PX may be disposed between the data lines DL, the gate lines GL, the power voltage supply lines PL and the reference voltage lines RL.

The data driver DD and the gate driver GD may be controlled by a timing controller TC. For example, the data driver DD may receive digital video data and a source timing signal from the timing controller TC, and the gate driver GD may receive clock signals, reset signals and start signals from the timing controller TC.

A light-emitting device 500 and a driving circuit DC may be disposed in each pixel area PX of the display panel DP. The light-emitting device 500 may emit light displaying a specific color. The driving circuit DC may be electrically connected to the light-emitting device 500. The driving circuit DC may supply a driving current corresponding to the data signal to the light-emitting device 500 according to the gate signal. For example, the driving circuit DC of each pixel area PX may be electrically connected to one of the gate lines GL, one of the data lines DL, one of the power voltage supply lines PL and one of the reference voltage lines RL. Thus, in the display apparatus according to the embodiment of the present disclosure, each pixel area PX of the display panel DP may realize a specific color having a luminance corresponding to the data signal according to the gate signal.

The driving current supplied to the light-emitting device 500 by the driving circuit DC may be maintained for one frame. For example, the driving circuit DC of each pixel area PX may include a first thin film transistor T1, a second thin film transistor T2, a third thin film transistor T3 and a storage capacitor Cst, as shown in FIG. 2.

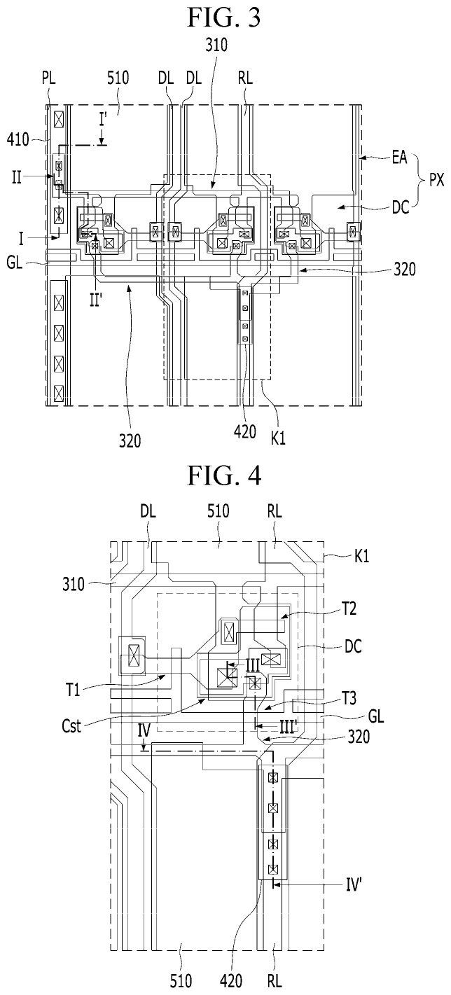

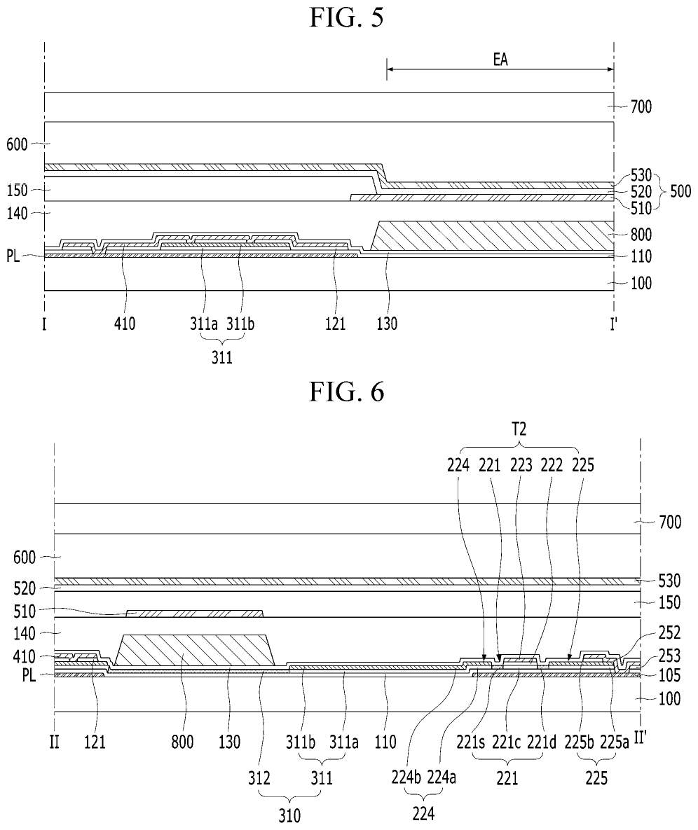

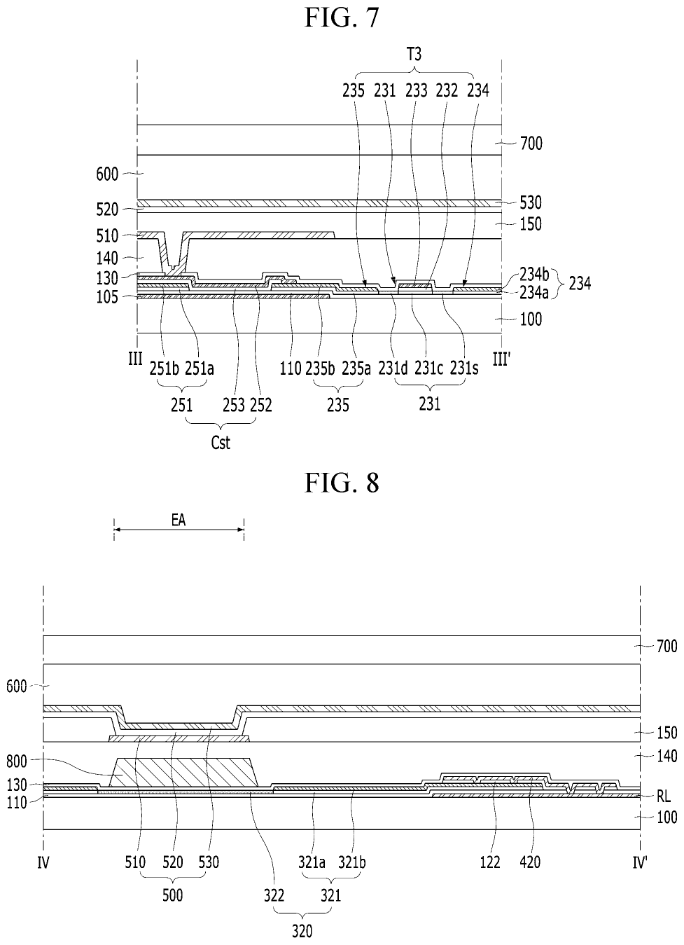

FIG. 3 is an enlarged view of a portion in the display apparatus according to the embodiment of the present disclosure. FIG. 4 is an enlarged view of K1 in FIG. 3. FIG. 5 is a view taken along I-I′ of FIG. 3. FIG. 6 is a view taken along II-II′ of FIG. 3. FIG. 7 is a view taken along III-III′ of FIG. 4. FIG. 8 is a view taken along IV-IV′ of FIG. 4.

Referring to FIGS. 2 to 8, the first thin film transistor T1 may transmit the data signal to the second thin film transistor T2 according to the gate signal. The first thin film transistor T1 may include a first semiconductor pattern, a first gate insulating layer, a first gate electrode, a first source electrode and a first drain electrode. The first semiconductor pattern may include a first channel region disposed between a first source region and a first drain region. The first gate insulating layer and the first gate electrode may be sequentially stacked on the first channel region of the first semiconductor pattern. For example, the first source region and the first drain region may be disposed outside the first gate insulating layer. The first source electrode may be electrically connected to the first source region of the first semiconductor pattern. The first drain electrode may be electrically connected to the first drain region of the first semiconductor pattern. For example, the first gate electrode of the first thin film transistor T1 may be electrically connected to the gate line GL, and the first source electrode of the first thin film transistor T1 may be electrically connected to the data line DL.

The second thin film transistor T2 may generate the driving current corresponding to the data signal. The light-emitting device 500 may be electrically connected to the second thin film transistor T2. For example, the second thin film transistor T2 may function as a driving thin film transistor applying the driving current corresponding to the data signal to the light-emitting device 500.

The second thin film transistor T2 may have a same structure as the first thin film transistor T1. For example, the second thin film transistor T2 may include a second semiconductor pattern 221, a second gate insulating layer 222, a second gate electrode 223, a second source electrode 224 and a second drain electrode 225, as shown in FIG. 6.

The second semiconductor pattern 221 may include a semiconductor. For example, the second semiconductor pattern 221 may include an oxide semiconductor, such as IGZO. The second semiconductor pattern 221 may include a second source region 221s, a second channel region 221c and a second drain region 221d. The second channel region 221c may be disposed between the second source region 221s and the second drain region 221d. The second source region 221s and the second drain region 221d may have a resistance lower than the second channel region 221c. For example, the second source region 221s and the second drain region 221d may be a conductive region of an oxide semiconductor. The second channel region 221c may be a region of an oxide semiconductor, which is not conductorized.

The second semiconductor pattern 221 may include a same material as the first semiconductor pattern. The second semiconductor pattern 221 may be formed simultaneously with the first semiconductor pattern. For example, the first source region and the first drain region of the first semiconductor pattern may be a conductive region of an oxide semiconductor, and the first channel region of the first semiconductor pattern may be a region of an oxide semiconductor, which is not conductorized. The first source region and the first drain region may have a same resistance as the second source region 221s and the second drain region 221d, and a resistance of the first channel region may be the same as a resistance of the second channel region 221c. The second semiconductor pattern 221 may have a same thickness as the first semiconductor pattern.

The second gate insulating layer 222 may be disposed on the second channel region 221c of the second semiconductor pattern 221. For example, the second source region 221s and the second drain region 221d of the second semiconductor pattern 221 may be disposed outside the second gate insulating layer 222. The second gate insulating layer 222 may include an insulating material. For example, the second gate insulating layer 222 may include an inorganic insulating material, such as silicon oxide (SiO) and silicon nitride (SiN).

The second gate insulating layer 222 may include a same material as the first gate insulating layer. For example, the second gate insulating layer 222 may be formed simultaneously with the first gate insulating layer. A thickness of the first gate insulating layer may be the same as a thickness of the second gate insulating layer 222.

The second gate electrode 223 may be disposed on the second gate insulating layer 222. For example, the second gate electrode 223 may overlap the second channel region 221c of the second semiconductor pattern 221. The second gate electrode 223 may include a conductive material. For example, the second gate electrode 223 may include a metal, such as aluminum (Al), chrome (Cr), copper (Cu), molybdenum (Mo), titanium (Ti) and tungsten (W). The second gate electrode 223 may be insulated from the second semiconductor pattern 221 by the second gate insulating layer 222. For example, a side of the second gate insulating layer 222 may be continuously with a side of the second gate electrode 223. The second gate electrode 223 may be electrically connected to the first drain electrode. For example, the second channel region 221c of the second semiconductor pattern 221 may have an electrical conductivity corresponding to the data signal according to the gate signal.

The second gate electrode 223 may be formed simultaneously with the first gate electrode. For example, the second gate electrode 223 may include a same material as the first gate electrode. A thickness of the first gate electrode may be the same as a thickness of the second gate electrode 223.

The second source electrode 224 may be electrically connected to the second source region 221s of the second semiconductor pattern 221. The second source electrode 224 may be in direct contact with the second source region 221s of the second semiconductor pattern 221. The second source electrode 224 may be spaced apart from the second gate electrode 223. For example, the second source electrode 224 may be in contact with a side of the second source region 221s of the second semiconductor pattern 221.

The second source electrode 224 may have a multi-layer structure. For example, the second source electrode 224 may have a stacked structure of a second source lower layer 224a and a second source upper layer 224b. The second source lower layer 224a may be disposed on a same layer as the second semiconductor pattern 221. For example, the side of the second source region 221s may be in contact with the second source lower layer 224a.

The second source lower layer 224a may include a same material as the second semiconductor pattern 221. For example, the second source lower layer 224a may include an oxide semiconductor. The second source lower layer 224a may be formed simultaneously with the second semiconductor pattern 221. For example, the second source lower layer 224 may be physically connected to the second semiconductor pattern 221. The second source lower layer 224a may be viewed as single pattern with the second semiconductor pattern 221. Thus, in the display apparatus according to the embodiment of the present disclosure, a contact resistance between the second source electrode 224 and the second semiconductor pattern 221 may be minimized. The second source lower layer 224a may have a same thickness as the second semiconductor pattern 221.

The second source upper layer 224b may be disposed on the second source lower layer 224a. For example, the second source upper layer 224b may not contact the side of the second source region 221s. The second source upper layer 224b may include a conductive material. A resistance of the second source upper layer 224b may be lower than a resistance of the second source lower layer 224a. For example, the second source upper layer 224b may include a metal, such as aluminum (Al), chrome (Cr), copper (Cu), molybdenum (Mo), titanium (Ti) and tungsten (W). Thus, in the display apparatus according to the embodiment of the present disclosure, the second source electrode 224 may have a sufficiently low resistance. The second source upper layer 224b may include a material different from the second gate electrode 223. For example, a lower surface of the second source upper layer 224b toward the second source lower layer 224a may be in direct contact with an upper surface of the second source lower layer 224a toward the second source upper layer 224b.

The second source electrode 224 may be formed simultaneously with the first source electrode. For example, the first source electrode may have a stacked structure of a first source lower layer and a first source upper layer. The first source lower layer may include a same material as the second source lower layer 224a. For example, the first source lower layer may be viewed as single pattern with the first semiconductor pattern. The first source upper layer may include a same material as the second source upper layer 224b. For example, a lower surface of the first source upper layer toward the first source lower layer may be in direct contact with an upper surface of the first source lower layer toward the first source upper layer. A resistance of the first source electrode may be the same as a resistance of the second source electrode 224.

The second drain electrode 225 may be electrically connected to the second drain region 221d of the second semiconductor pattern 221. The second drain electrode 225 may be in direct contact with the second drain region 221d of the second semiconductor pattern 221. The second drain electrode 225 may be spaced apart from the second gate electrode 223. For example, the second drain electrode 225 may be in direct contact with a side of the second drain region 221d of the second semiconductor pattern 221.

The second drain electrode 225 may have a multi-layer structure. The second drain electrode 225 may have a same structure as the second source electrode 224. For example, the second drain electrode 225 may have a stacked structure of a second drain lower layer 225a and a second drain upper layer 225b. The second drain lower layer 225a may be disposed on a same layer as the second semiconductor pattern 221. For example, the side of the second drain region 221d may be contact with the second drain lower layer 225a.

The second drain lower layer 225a may include a same material as the second semiconductor pattern 221. For example, the second drain lower layer 225a may include an oxide semiconductor. The second drain lower layer 225a may be formed simultaneously with the second semiconductor pattern 221. For example, the second drain lower layer 225a may be physically connected to the second semiconductor pattern 221. The second drain lower layer 225a may be viewed as single pattern with the second semiconductor pattern. Thus, in the display apparatus according to the embodiment of the present disclosure, a contact resistance between the second drain electrode 225 and the second semiconductor pattern 221 may be minimized. The second drain lower layer 225a may have a same thickness as the second semiconductor pattern 221.

The second drain upper layer 225b may be disposed on the second drain lower layer 225a. For example, the second drain upper layer 225b may not contact the side of the second drain region 221d. The second drain upper layer 225b may include a conductive material. A resistance of the second drain upper layer 225b may be lower than a resistance of the second drain lower layer 225a. For example, the second drain upper layer 225b may include a metal, such as aluminum (Al), chrome (Cr), copper (Cu), molybdenum (Mo), titanium (Ti) and tungsten (W). Thus, in the display apparatus according to the embodiment of the present disclosure, the second drain electrode 225 may have a sufficiently low resistance. The second drain upper layer 225a may include a material different from the second gate electrode 223. For example, a lower surface of the second drain upper layer 225b toward the second drain lower layer 225a may be in direct contact with an upper surface of the second drain lower layer 225a toward the second drain upper layer 225b.

The second drain electrode 225 may be formed simultaneously with the first drain electrode. For example, the first drain electrode may have a stacked structure of a first drain lower layer and a first drain upper layer. The first drain lower layer may include a same material as the second drain lower layer 225a. For example, the first drain lower layer may be viewed as single pattern with first semiconductor pattern. The first drain upper layer may include a same material as the second drain upper layer 225b. For example, a lower surface of the first drain upper layer toward the first drain lower layer may be in direct contact with an upper surface of the first drain lower layer toward the first drain upper layer. A resistance of the first drain electrode may be the same as a resistance of the second drain electrode 225.

The first thin film transistor T1 and the second thin film transistor T2 may be disposed on a device substrate 100. The device substrate 100 may include an insulating material. The device substrate 100 may include a transparent material. For example, the device substrate 100 may include glass or plastic.

A light-blocking pattern 105 may be disposed between the device substrate 100 and the second thin film transistor T2. The light-blocking pattern 105 may prevent changes in characteristics of the second thin film transistor T2 due to external light. For example, the light-blocking pattern 105 may overlap the second semiconductor pattern 221 of the second thin film transistor T2. The light-blocking pattern 105 may include a material capable of blocking light. The light-blocking pattern 105 may include a conductive material. For example, the light-blocking pattern 105 may include a metal, such as aluminum (Al), chrome (Cr), copper (Cu), molybdenum (Mo), titanium (Ti) and tungsten (W).

The light-blocking pattern 105 may be insulated from the second thin film transistor T2. For example, a buffer insulating layer 110 may be disposed between the light-blocking pattern 105 and the second thin film transistor T2. The buffer insulating layer 110 may extend beyond the light-blocking pattern 105. For example, a side of the light-blocking pattern 105 may be covered by the buffer insulating layer 110. The buffer insulating layer 110 may extend along an upper surface of the device substrate 100 toward the second thin film transistor T2. For example, the first thin film transistor T1 may be disposed on the buffer insulating layer 110. Thus, in the display apparatus according to the embodiment of the present disclosure, pollution due to the device substrate 100 in a process of forming the first thin film transistor T1 and the second thin film transistor T2 may be prevented.

The second thin film transistor T2 may be disposed between the power voltage supply line PL and the light-emitting device 500. For example, the second source electrode 224 of the second thin film transistor T2 may be electrically connected to the power voltage supply line PL through a first connection wiring 310. The first connection wiring 310 may be disposed on a same layer as the second source electrode 224 of the second thin film transistor T2. For example, the first connection wiring 310 may be disposed on the buffer insulating layer 110, as shown in FIGS. 5 and 6.

The first connection wiring 310 may include a first opaque wiring region 311 and a first transparent wiring region 312. The first opaque wiring region 311 and the first transparent wiring region 312 may be disposed side by side on the buffer insulating layer 110. A transmittance of the first transparent wiring region 312 may be higher than a transmittance of the first opaque wiring region 311. The first transparent wiring region 312 may have a thickness smaller than the first opaque wiring region 311. For example, the first opaque wiring region 311 may have a stacked structure of a first lower wiring layer 311a and a first upper wiring layer 311b, and the first transparent wiring region 312 may have a single-layer structure.

The first transparent wiring region 312 may be disposed on a same layer as the first lower wiring layer 311a of the first opaque wiring region 311. The first transparent wiring region 312 may include a same material as the first lower wiring layer 311a. The first transparent wiring region 312 may have a resistance lower than the first lower wiring layer 311a. For example, the first lower wiring layer 311a may be a region of an oxide semiconductor, which is not conductorized, and the first transparent wiring region 312 may be a conductive region of an oxide semiconductor. The first transparent wiring region 312 may be in direct contact with the first lower wiring layer 311a. For example, a side of the first transparent wiring region 312 may be physically connected to a side of the first lower wiring layer 311a. The first transparent wiring region 312 may be viewed as single pattern with the first lower wiring layer 311a. The first transparent wiring region 312 may have a same thickness as the first lower wiring layer 311a.

The first upper wiring layer 311b may be disposed on the first lower wiring layer 311a. For example, a lower surface of the first upper wiring layer 311b toward the first lower wiring layer 311a may be in direct contact with an upper surface of the first lower wiring layer 311a toward the first upper wiring layer 311b. The first upper wiring layer 311b may not contact with the first transparent wiring region 312. The first upper wiring layer 311b may include a conductive material. The first upper wiring layer 311b may have a resistance lower than the first lower wiring layer 311a and the first transparent wiring region 312. For example, the first upper wiring layer 311b may include a metal, such as aluminum (Al), chrome (Cr), copper (Cu), molybdenum (Mo), titanium (Ti) and tungsten (W).

The first connection wiring 310 may be cut by a repair process. For example, the repair process may include a process of irradiating laser to a portion of the first opaque wiring region 311 of the first connection wiring 310. The laser may pass through the first lower wiring layer 311a, but the first upper wiring layer 311b may be heated by the laser. Thus, in the display apparatus according to the embodiment of the present disclosure, a portion of the first upper wiring layer 311b may be melted by the irradiation of the laser. And, in the display apparatus according to the embodiment of the present disclosure, since the first lower wiring layer 311a is in direct contact with the first upper wiring layer 311b, a portion of the first lower wiring layer 311a may be melted due to heat generated from the first upper wiring layer 311b. That is, in the display apparatus according to the embodiment of the present disclosure, a portion of the first upper wiring layer 311b and a portion of the first lower wiring layer 311a may be removed by the irradiation of the laser for the repair process.

The second source electrode 224 of the second thin film transistor T2 may be electrically connected to the first opaque wiring region 311 of the first connection wiring 310. The first opaque wiring region 311 of the first connection wiring 310 may be formed using a process of forming the second source electrode 224. For example, the first lower wiring layer 311a may include a same material as the second source lower layer 224a, and the first upper wiring layer 311b may include a same material as the second source upper layer 224b. A resistance of the second source upper layer 224b may be the same as a resistance of the first upper wiring layer 311b. For example, the second source lower layer 224a may be a region of an oxide semiconductor, which is not conductorized. The second source lower layer 224a may have a same resistance as the second channel region 221c of the second semiconductor pattern 221.

The first opaque wiring region 311 of the first connection wiring 310 may be in direct contact with the second source electrode 224. For example, the first lower wiring layer 311a may be physically connected to the second source lower layer 224a, and the first upper wiring layer 311b may be physically connected to the second source upper layer 224b. The first lower wiring layer 311a may be viewed as single pattern with the second source lower layer 224a, and the first upper wiring layer 311b may be viewed as single pattern with the second source upper layer 224b. For example, the first lower wiring layer 311a may be formed simultaneously with the second source lower layer 224a, and the first upper wiring layer 311b may be formed simultaneously with the second source upper layer 224b. Thus, in the display apparatus according to the embodiment of the present disclosure, process efficiency may be improved.

The power voltage supply line PL may be disposed on a layer different from the first connection wiring 310. For example, the power voltage supply line PL may be disposed between the device substrate 100 and the buffer insulating layer 110. The power voltage supply line PL may be disposed on a same layer as the light-blocking pattern 105. The power voltage supply line PL may include a same material as the light-blocking pattern 105. For example, the power voltage supply line PL may include a metal, such as aluminum (Al), chrome (Cr), copper (Cu), molybdenum (Mo), titanium (Ti) and tungsten (W). The power voltage supply line PL may be formed simultaneously with the light-blocking pattern 105. For example, the first transparent wiring region 312 of the first connection wiring 310 may have a transmittance higher than the power voltage supply line PL.

The power voltage supply line PL may be electrically connected to the first opaque wiring region 311 of the first connection wiring 310 through a first intermediate electrode 410. The first intermediate electrode 410 may include a conductive material. The first intermediate electrode 410 may have a relative low resistance. For example, the first intermediate electrode 410 may include a metal, such as aluminum (Al), chrome (Cr), copper (Cu), molybdenum (Mo), titanium (Ti) and tungsten (W). The first intermediate electrode 410 may include a material different from the first upper wiring layer 311b. The first intermediate electrode 410 may be disposed on a layer different from the first upper wiring layer 311b. For example, a portion of the first upper wiring layer 311b may be covered by a first intermediate insulating layer 121, and the first intermediate electrode 410 on the first intermediate insulating layer 121 may include a region directly contacting the first upper wiring layer 311b by penetrating the first intermediate insulating layer 121 and a region directly contacting the power voltage supply line PL by penetrating the first intermediate insulating layer 121 and the buffer insulating layer 110.

The first intermediate insulating layer 121 may include an insulating material. For example, the first intermediate insulating layer 121 may include an inorganic insulating material, such as silicon oxide (SiO) and silicon nitride (SiN). The first intermediate insulating layer 121 may include a same material as the second gate insulating layer 222. For example, the first intermediate insulating layer 121 may be formed simultaneously with the second gate insulating layer 222, and the first intermediate electrode 410 may be formed simultaneously with the second gate electrode 223. The first intermedia electrode 410 may include a same material as the second gate electrode 223.

The third thin film transistor T3 may reset the storage capacitor Cst according to the gate signal. The third thin film transistor T3 may be disposed on a same layer as the second thin film transistor T2. For example, the third thin film transistor T3 may be disposed on the buffer insulating layer 110. The third thin film transistor T3 may have a same structure as the second thin film transistor T2. For example, the third thin film transistor T3 may include a third semiconductor pattern 231, a third gate insulating layer 232, a third gate electrode 233, a third source electrode 234 and a third drain electrode 235, as shown in FIG. 7.

The third semiconductor pattern 231 may include a semiconductor pattern. For example, the third semiconductor pattern 231 may include an oxide semiconductor, such as IGZO. The third semiconductor pattern 231 may include a third channel region 231c disposed between a third source region 231s and a third drain region 231d. The third source region 231s and the third drain region 231d may have a resistance lower than the third channel region 231c. For example, the third source region 231s and the third drain region 231d may be a conductive region of an oxide semiconductor. The third channel region 231c may be a region of an oxide semiconductor, which is not conductorized.

The third semiconductor pattern 231 may be formed simultaneously with the second semiconductor pattern 221. For example, the third semiconductor pattern 231 may include a same material as the second semiconductor pattern 221. The third source region 231s and the third drain region 231d may have a same resistance as the second source region 221s and the second drain region 221d. A resistance of the third channel region 231c may be the same as a resistance of the second channel region 221c. The third semiconductor pattern 231 may have a same thickness as the second semiconductor pattern 221.

The third gate insulating layer 232 may be disposed on the third channel region 231c of the third semiconductor pattern 231. For example, the third source region 231s and the third drain region 231d of the third semiconductor pattern 231 may be disposed outside the third gate insulating layer 232. The third gate insulating layer 232 may include an insulating material. For example, the third gate insulating layer 232 may include an inorganic insulating material, such as silicon oxide (SiO) and silicon nitride (SiN).

The third gate insulating layer 232 may include a same material as the second gate insulating layer 222. For example, the third gate insulating layer 232 may be formed simultaneously with the second gate insulating layer 222. A thickness of the third gate insulating layer 232 may be the same as a thickness of the second gate insulating layer 222.

The third gate electrode 233 may be disposed on the third gate insulating layer 232. For example, the third gate electrode 233 may overlap the third channel region 231c of the third semiconductor pattern 231. The third gate electrode 233 may include a conductive material. For example, the third gate electrode 233 may include a metal, such as aluminum (Al), chrome (Cr), copper (Cu), molybdenum (Mo), titanium (Ti) and tungsten (W). The third gate electrode 233 may be insulated from the third semiconductor pattern 231 by the third gate insulating layer 232. For example, a side of the third gate insulating layer 232 may be continuously with a side of the third gate electrode 233. The third gate electrode 233 may be electrically connected to the gate line GL. For example, the gate signal may be simultaneously applied to the first gate electrode and the third gate electrode 233. The third thin film transistor T3 may be turn-on/off simultaneously with the first thin film transistor T1.

The third gate electrode 233 may be formed simultaneously with the second gate electrode 223. For example, the third gate electrode 233 may include a same material as the second gate electrode 223. A thickness of the third gate electrode 233 may be the same as a thickness of the second gate electrode 223.

The third source electrode 234 may be electrically connected to the third source region 231s of the third semiconductor pattern 231. The third source electrode 234 may be in direct contact with the third source region 231s of the third semiconductor pattern 231. The third source electrode 234 may be spaced apart from the third gate electrode 233. For example, the third source electrode 234 may be in direct contact with a side of the third source region 231s of the third semiconductor pattern 231.

The third source electrode 234 may have a multi-layer structure. The third source electrode 234 may have a same structure as the second source electrode 224. For example, the third source electrode 234 may have a stacked structure of a third source lower layer 234a and a third source upper layer 234b. The third source electrode 234 may be formed simultaneously with the second source electrode 224. For example, the third source lower layer 234a may include a same material as the second source lower layer 224a, and the third source upper layer 234b may include a same material as the second source upper layer 224b. The third source lower layer 234a may be a region of an oxide semiconductor, which is not conductorized. A side of the third source lower layer 234a may be physically connected to a side of the third source region 231s. For example, the third source lower layer 234a may be viewed as single pattern with the third semiconductor pattern 231. A lower surface of the third source upper layer 234b toward the third source lower layer 234a may be in direct contact with an upper surface of the third source lower layer 234a toward the third source upper layer 234b. A resistance of the third source electrode 234 may be the same as a resistance of the second source electrode 224.

The third drain electrode 235 may be electrically connected to the third drain region 231d of the third semiconductor pattern 231. The third drain electrode 235 may be in direct contact with the third drain region 231d of the third semiconductor pattern 231. The third drain electrode 235 may be spaced apart from the third gate electrode 233. For example, the third drain electrode 235 may be in direct contact with a side of the third drain region 231d of the third semiconductor pattern 231.

The third drain electrode 235 may have a multi-layer structure. The third drain electrode 235 may have a same structure as the second drain electrode 225. For example, the third drain electrode 235 may have a stacked structure of a third drain lower layer 235a and a third drain upper layer 235b. The third drain electrode 235 may be formed simultaneously with the second drain electrode 225. For example, the third drain lower layer 235a may include a same material as the second drain lower layer 225a, and the third drain upper layer 235b may include a same material as the second drain upper layer 225b. The third drain lower layer 235a may be a region of an oxide semiconductor, which is not conductorized. A side of the third drain lower layer 235a may be physically connected to a side of the third drain region 231d. For example, the third drain lower layer 235a may be viewed as single pattern with the third semiconductor pattern 231. A lower surface of the third drain upper layer 235b toward the third drain lower layer 235a may be in direct contact with an upper surface of the third drain lower layer 235a toward the third drain upper layer 235b. A resistance of the third drain electrode 235 may be the same as a resistance of the second drain electrode 225.

The third thin film transistor T3 may be disposed between the reference voltage supply line PL and the storage capacitor Cst. For example, the third source electrode 234 of the third thin film transistor T3 may be electrically connected to the reference voltage supply line PL through a second connection wiring 320. The second connection wiring 320 may be disposed on a same layer as the third source electrode 234 of the third thin film transistor T3. For example, the second connection wiring 320 may be disposed on the buffer insulating layer 110, as shown in FIG. 8. The second connection wiring 320 may be disposed on a same layer as the first connection wiring 310.

The second connection wiring 320 may include a second opaque wiring region 321 and a second transparent wiring region 322. The second opaque wiring region 321 and the second transparent region 322 may be disposed side by side on the buffer insulating layer 110. A transmittance of the second transparent wiring region 322 may be higher than a transmittance of the second opaque wiring region 321. The second transparent wiring region 322 may have a thickness TH2 smaller than a thickness TH1 of the second opaque wiring region 321 (FIG. 12). For example, the second opaque wiring region 321 may have a stacked structure of a second lower wiring layer 321a and a second upper wiring layer 321b, and the second transparent wiring region 322 may have a single-layer structure.

The second transparent wiring region 322 may be disposed on a same layer as the second lower wiring layer 321a of the second opaque wiring region 321. The second transparent wiring region 322 may include a same material as the second lower wiring layer 321a. The second transparent wiring region 322 may have a resistance lower than the second lower wiring layer 321a. For example, the second lower wiring layer 321a may be a region of an oxide semiconductor, which is not conductorized, and the second transparent wiring region 322 may be a conductive region of an oxide semiconductor. The second transparent wiring region 322 may be in direct contact with the second lower wiring layer 321a. For example, a side of the second transparent wiring region 322 may be physically connected to a side of the second lower wiring layer 321a. The second transparent wiring region 322 may be viewed as single pattern with the second lower wiring layer 321a. The second transparent wiring region 322 may have a same thickness as the second lower wiring layer 321a.

The second upper wiring layer 321b may be disposed on the second lower wiring layer 321a. For example, a lower surface of the second upper wiring layer 321b toward the second lower wiring layer 321a may be in direct contact with an upper surface of the second lower wiring layer 321a toward the second upper wiring layer 321b. The second upper wiring layer 321b may not contact with the second transparent wiring region 322. The second upper wiring layer 321b may include a conductive material. The second upper wiring layer 321b may have a resistance lower than the second lower wiring layer 321a and the second transparent wiring region 322. For example, the second upper wiring layer 321b may include a metal, such as aluminum (Al), chrome (Cr), copper (Cu), molybdenum (Mo), titanium (Ti) and tungsten (W).

The second connection wiring 320 may be formed simultaneously with the first connection wiring 310. For example, the second lower wiring layer 321a and the second transparent wiring region 322 may include a same material as the first lower wiring layer 311a and the first transparent wiring region 312, and the second upper wiring layer 321b may include a same material as the first upper wiring layer 311b. A resistance of the second transparent wiring region 322 may be the same as a resistance of the first transparent wiring region 312.

The second connection wiring 320 may be cut by a repair process. For example, the repair process may include a process of irradiating laser to a portion of the second opaque wiring region 321 of the second connection wiring 320. Thus, in the display apparatus according to the embodiment of the present disclosure, a portion of the second upper wiring layer 321b and a portion of the second lower wiring layer 321a may be removed by the irradiation of the laser for the repair process.

The third source electrode 234 of the third thin film transistor T3 may be electrically connected to the second opaque wiring region 321 of the second connection wiring 320. The second connection wiring 320 may be formed using a process of forming the third thin film transistor T3. For example, the second lower wiring layer 321a and the second transparent wiring region 322 may be formed on a same layer as the third semiconductor layer 321, and the second upper wiring layer 321b may be formed of a same material as the third source upper layer 234b and the third drain upper layer 235b. The second transparent wiring region 322 may have a same resistance as the third source region 321s and the third drain region 321d of the third semiconductor pattern 321, and the second lower wiring layer 321a may have a same resistance as the third channel region 321c of the third semiconductor pattern 321. Thus, in the display apparatus according to the embodiment of the present disclosure, the process efficiency may be effectively improved.

The second opaque wiring region 321 of the second connection wiring 320 may have a same stacked structure as the third source electrode 234. The second opaque wiring region 321 of the second connection wiring 320 may be in direct contact with the third source electrode 234. For example, the second lower wiring layer 321a may be physically connected to the third source lower layer 234a, and the second upper wiring layer 321b may be physically connected to the third source upper layer 234b. The second lower wiring layer 321a may be viewed as single pattern with the third source lower layer 234a, and the second upper wiring layer 321b may be viewed as single pattern with the third source upper layer 234b.

The reference voltage supply line RL may be disposed on a layer different from the second connection wiring 320. For example, the reference voltage supply line RL may be disposed between the device substrate 100 and the buffer insulating layer 110. The reference voltage supply line RL may be disposed on a same layer as the power voltage supply line PL. The reference voltage supply line RL may include a same material as the power voltage supply line PL. For example, the reference voltage supply line RL may include a metal, such as aluminum (Al), chrome (Cr), copper (Cu), molybdenum (Mo), titanium (Ti) and tungsten (W). The reference voltage supply line RL may be formed simultaneously with the power voltage supply line PL. For example, the second transparent wiring region 322 of the second connection wiring 320 may have a transmittance higher than the reference voltage supply line RL.

The reference voltage supply line RL may be electrically connected to the second opaque wiring region 321 of the second connection wiring 320 through a second intermediate electrode 420. The second intermediate electrode 420 may include a conductive material. The second intermediate electrode 420 may have a relative low resistance. For example, the second intermediate electrode 420 may include a metal, such as aluminum (Al), chrome (Cr), copper (Cu), molybdenum (Mo), titanium (Ti) and tungsten (W). The second intermediate electrode 420 may include a material different from the second upper wiring layer 321b. The second intermediate electrode 420 may be disposed on a layer different from the second upper wiring layer 321b. For example, a portion of the second upper wiring layer 321b may be covered by a second intermediate insulating layer 122, and the second intermediate electrode 420 on the second intermediate insulating layer 122 may include a region directly contacting the second upper wiring layer 321b by penetrating the second intermediate insulating layer 122 and a region directly contacting the reference voltage supply line RL by penetrating the second intermediate insulating layer 122 and the buffer insulating layer 110.

The second intermediate insulating layer 122 may include an insulating material. For example, the second intermediate insulating layer 122 may include an inorganic insulating material, such as silicon oxide (SiO) and silicon nitride (SiN). The second intermediate insulating layer 122 may include a same material as the third gate insulating layer 232. For example, the second intermediate insulating layer 122 may be formed simultaneously with the third gate insulating layer 232, and the second intermediate electrode 420 may be formed simultaneously with the third gate electrode 233. The second intermedia electrode 420 may include a same material as the third gate electrode 233.

The storage capacitor Cst may maintain a signal applied to the second gate electrode 223 of the second thin film transistor T2 for one frame. For example, the storage capacitor Cst may be electrically connected between the second gate electrode 223 and the second drain electrode 225 of the second thin film transistor T2. The storage capacitor Cst may have a stacked structure of conductive patterns 251 and 252, which are insulated from each other. For example, the storage capacitor Cst may have a structure in which a capacitor insulating layer 253 is disposed between a first conductive pattern 251 and a second conductive pattern 252, as shown in FIG. 7.

The first conductive pattern 251 may be electrically connected to the second gate electrode 223 of the second thin film transistor T2. For example, the first conductive pattern 251 may be electrically connected to the first drain electrode of the first thin film transistor T1. The first conductive pattern 251 may be disposed on a same layer as the first drain electrode. For example, the first conductive pattern 251 may be disposed on the buffer insulating layer 110. The first conductive pattern 251 may have a same stacked structure as the first drain electrode. For example, the first conductive pattern 251 may have a stacked structure of a lower pattern layer 251a and an upper pattern layer 251b.

The first conductive pattern 251 may be formed using a process of forming the first drain electrode. For example, the lower pattern layer 251a may include a same material as the first drain lower layer of the first drain electrode, and the upper pattern layer 251b may include a same material as the first drain upper layer of the first drain electrode. The lower pattern layer 251a may be in direct contact with the first drain lower layer, and the upper pattern layer 251b may be in direct contact with the first drain upper layer. For example, a side of the lower pattern layer 251a may be physically connected to a side of the first drain lower layer, and a side of the upper pattern layer 251b may be physically connected to a side of the first drain upper layer. The lower pattern layer 251a may be viewed as single pattern with the first drain lower layer, and the upper pattern layer 251b may be viewed as single pattern with the first drain upper layer.

The second conductive pattern 252 may be disposed on the upper pattern layer 251b of the first conductive pattern 251. For example, the second conductive pattern 252 may include a region overlapping with the first conductive pattern 251. The second conductive pattern 252 may include a conductive material. The second conductive pattern 252 may include a material having a relative low resistance. For example, the second conductive pattern 252 may include a metal, such as aluminum (Al), chrome (Cr), copper (Cu), molybdenum (Mo), titanium (Ti) and tungsten (W).

The second conductive pattern 252 may be electrically connected to the second drain electrode 225 of the second thin film transistor T2. The second conductive pattern 252 may be electrically connected to the third drain electrode 235 of the third thin film transistor T3. The second conductive pattern 252 may be in direct contact with the third drain upper layer 235b of the third drain electrode 235. For example, an end of the second conductive pattern 252 may partially cover an upper surface of the third drain upper layer 235b opposite to the device substrate 100, as shown in FIG. 7.

The second conductive pattern 252 may be insulated from the first conductive pattern 251 by the capacitor insulating layer 253. The capacitor insulating layer 253 may include an insulating material. For example, the capacitor insulating layer 253 may include an inorganic insulating material, such as silicon oxide (SiO) and silicon nitride (SiN). The capacitor insulating layer 253 may include a same material as the third gate insulating layer 232. For example, the capacitor insulating layer 253 may be formed simultaneously with the third gate insulating layer 232, and the second conductive pattern 252 may be formed simultaneously with the third gate electrode 233. The second conductive pattern 252 may include a same material as the third gate electrode 233.

The light-blocking pattern 105 may extend between the device substrate 100 and the first conductive pattern 251. A specific voltage may be applied to the light-blocking pattern 105. For example, the light-blocking pattern 105 may be electrically connected to the second drain electrode 225 by the second conductive pattern 252, as shown in FIG. 6. That is, in the display apparatus according to the embodiment of the present disclosure, a portion of the light-blocking pattern 105 may functions as a conductive pattern of the storage capacitor Cst. For example, in the display apparatus according to the embodiment of the present disclosure, the storage capacitor Cst may have a structure in which a capacitor formed between the light-blocking pattern 105 and the first conductive pattern 251 and a capacitor formed between the first conductive pattern 251 and the second conductive pattern 252 are connected in series. Thus, in the display apparatus according to the embodiment of the present disclosure, a size of the storage capacitor Cst may be reduced. Therefore, in the display apparatus according to the embodiment of the present disclosure, an area occupied by the driving circuit DC in each pixel area PX may be reduced.

A lower passivation layer 130 may be disposed on the driving circuit DC of each pixel area PX. The lower passivation layer 130 may prevent damages of the driving circuit DC in each pixel area PX due to external impact and moisture. For example, the lower passivation layer 130 may completely cover the first thin film transistor T1, the second thin film transistor T2, the third thin film transistor T3 and the storage capacitor Cst of each pixel area PX. The lower passivation layer 130 may include an insulating material. For example, the lower passivation layer 130 may include an inorganic insulating material, such as silicon oxide (SiO) and silicon nitride (SiN).

An over-coat layer 140 may be disposed on the lower passivation layer 130. The over-coat layer 140 may remove a thickness difference due to the driving circuit DC of each pixel area PX. For example, an upper surface of the over-coat layer 140 opposite to the device substrate 100 may be a flat surface. The over-coat layer 140 may include an insulating material. The over-coat layer 140 may include a material different from the lower passivation layer 130. For example, the over-coat layer 140 may include an organic insulating material.

A bank insulating layer 150 may be disposed on the over-coat layer 140. The bank insulating layer 150 may include an insulating material. For example, the bank insulating layer 150 may include an organic insulating material. The bank insulating layer 150 may include a material different from the over-coat layer 140.

The bank insulating layer 150 may define an emission area EA in each pixel area PX. For example, the bank insulating layer 150 may include an opening disposed in each pixel area PX. The driving circuit DC of each pixel area PX may be disposed outside the emission area EA of the corresponding pixel area PX. For example, the first thin film transistor T1, the second thin film transistor T2, the third thin film transistor T3 and the storage capacitor Cst of each pixel area PX may be disposed between the device substrate 100 and the bank insulating layer 150.

The light-emitting device 500 of each pixel area PX may be disposed in the emission area EA of the corresponding pixel area PX adjacent to the bank insulating layer 150. For example, the light-emitting device 500 of each pixel area PX may include a first electrode 510, a light-emitting layer 520 and a second electrode 530, which are sequentially stacked on the emission area EA of the corresponding pixel area PX.

The first electrode 510 may be disposed on the over-coat layer 140. For example, a lower surface of the first electrode 510 toward the device substrate 100 may be in direct contact with the upper surface of the over-coat layer 140. Thus, in the display apparatus according to the embodiment of the present disclosure, luminance deviation according generating position of the light emitted from each light-emitting device 500 may be prevented. The first electrode 510 may include a conductive material. The first electrode 510 may include a material having a relatively high transmittance. For example, the first electrode 510 may be a transparent electrode made of a transparent conductive material, such as ITO and IZO.

The first electrode 510 may be electrically connected to the second thin film transistor T2. For example, the first electrode 510 may be in direct contact with the second conductive pattern 252 by penetrating the lower passivation layer 130 and the over-coat layer 140, as shown in FIG. 7. Thus, in the display apparatus according to the embodiment of the present disclosure, the driving current generated by the driving circuit DC of each pixel area PX may be supplied to the first electrode 510 of the corresponding pixel area PX for one frame.

The light-emitting layer 520 may generate light having luminance corresponding to a voltage difference between the first electrode 510 and the second electrode 530. For example, the light-emitting layer 520 may include an emission material layer (EML) having an emission material. The emission material may include an organic material, an inorganic material or a hybrid material. For example, the display apparatus according to the embodiment of the present disclosure may be an organic light-emitting display apparatus including an organic emission material.

The light-emitting layer 520 may have a multi-layer structure. For example, the light-emitting layer 520 may further include at least one of a hole injection layer (HIL), a hole transport layer (HTL), an electron transport layer (ETL) and an electron injection layer (EIL). Thus, in the display apparatus according to the embodiment of the present disclosure, the emission efficiency of the light-emitting layer 520 may be improved.

The second electrode 530 may include a conductive material. The second electrode 530 may include a material different from the first electrode 510. The second electrode 530 may have a reflectance higher than the first electrode 510. For example, the second electrode 530 may include a metal, such as aluminum (Al) and silver (Ag). Thus, in the display apparatus according to the embodiment of the present disclosure, the light generated by the light-emitting layer 520 may be emitted outside through the first electrode 510 and the device substrate 100.

The light-emitting device 500 of each pixel area PX may be controlled from the light-emitting device 500 of adjacent pixel area PX, independently. For example, the first electrode 510 of each pixel area PX may be spaced apart from the first electrode 510 of adjacent pixel area PX. The first electrode 510 of each pixel area PX may be insulated from the first electrode 510 of adjacent pixel area PX. For example, the bank insulating layer 150 may cover an edge of the first electrode 510 in each pixel area PX.

The light-emitting layer 520 and the second electrode 530 of each pixel area PX may be stacked on a portion of the first electrode 510 of the corresponding pixel area PX exposed by the bank insulating layer 150. The light-emitting layer 520 and the second electrode 520 of each pixel area PX may extend onto the bank insulating layer 150. The light-emitting layer 520 of each pixel area PX may be connected to the light-emitting layer 520 of adjacent pixel area PX. The light emitted from the light-emitting device 500 of each pixel area PX may display a same color as the light emitted from the light-emitting device 500 of adjacent pixel area PX. For example, the light-emitting device 500 of each pixel area PX may emit white light. Each of the pixel area PX may realize a color different from adjacent pixel area PX. For example, a color filter 800 overlapping with the emission area EA may be disposed in each pixel area PX. The color filter 800 may realize a specific color using passing light. For example, the color filter 800 of each pixel area PX may be disposed on a path of the light emitted from the light-emitting device 500 in the corresponding pixel area PX. The color filter 800 of each pixel area PX may be disposed between the device substrate 100 and the light-emitting device 500 of the corresponding pixel area PX. For example, the color filter 800 of each pixel area PX may be disposed between the lower pas sivation layer 130 and the over-coat layer 140 of the corresponding pixel area PX. A thickness difference due to the color filter 800 of each pixel area PX may be removed by the over-coat layer 140.

A voltage applied to the second electrode 530 of each pixel area PX may be the same as a voltage applied to the second electrode 530 of adjacent pixel area PX. For example, the second electrode 530 of each pixel area PX may be electrically connected to the second electrode 530 of adjacent pixel area PX. The second electrode 530 of each pixel area PX may include a same material as the second electrode 530 of adjacent pixel area PX. For example, the second electrode 530 of each pixel area PX may be formed simultaneously with the second electrode 530 of adjacent pixel area PX. Thus, in the display apparatus according to the embodiment of the present disclosure, a process of forming the second electrode 530 in each pixel area PX may be simplified.

The first connection wirings 310 and/or the second connection wirings 320 may include a region overlapping with the emission area EA of one of the pixel areas PX. For example, the first transparent wiring region 312 of each first connection wiring 310 and the second transparent wiring region 322 of each second connection wiring 320 may be disposed between the first electrode 510 of one of the pixel areas PX and the device substrate 100. Thus, in the display apparatus according to the embodiment of the present disclosure, the light emitted from the light-emitting device 500 of each pixel area PX may be not blocked by the first connection wirings 310 and the second connection wirings 320. That is, in the display apparatus according to the embodiment of the present disclosure, an area of the emission area EA defined in each pixel area PX may be increased. Therefore, in the display apparatus according to the embodiment of the present disclosure, the luminance efficiency of each pixel area PX may be improved.

An encapsulation substrate 700 may be disposed on the second electrode 530 of each pixel area PX. The encapsulation substrate 700 may prevent damages of the light-emitting devices 500 due to the external impact and moisture. For example, the encapsulation substrate 700 may include a material having a specific strength or higher. The encapsulation substrate 700 may include a material having a relatively high thermal-conductivity. For example, the encapsulation substrate 700 may include a metal, such as aluminum (Al), nickel (Ni) and iron (Fe). Thus, in the display apparatus according to the embodiment of the present disclosure, heat generated from the driving circuit DC and the light-emitting device 500 of each pixel area PX may be emitted through the encapsulation substrate 700. Therefore, in the display apparatus according to the embodiment of the present disclosure, the deterioration of the light-emitting layers 520 may be minimized.

The encapsulation substrate 700 may be attached to the device substrate 100 in which the light-emitting devices 500 are formed. For example, an encapsulating element 600 may be disposed in a space between the light-emitting devices 500 and the encapsulation substrate 700. The encapsulating element 600 may include an adhesive material. The encapsulating element 600 may include an insulating material. For example, the encapsulating element 600 may include an olefin-based material. The encapsulating element 600 may have a relative low water vapor transmission rate (WVTR). Thus, in the display apparatus according to the embodiment of the present disclosure, penetration of the external moisture through the encapsulating element 600 may be blocked.

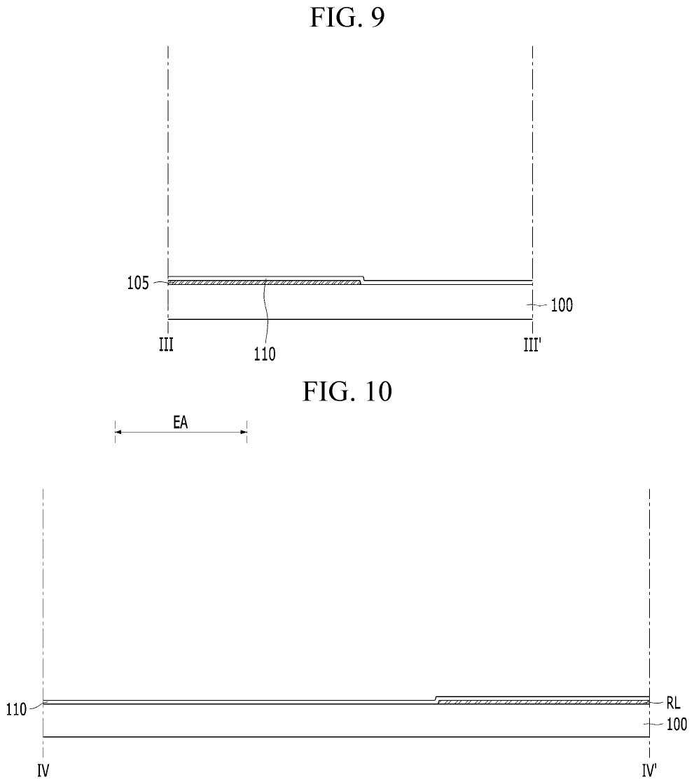

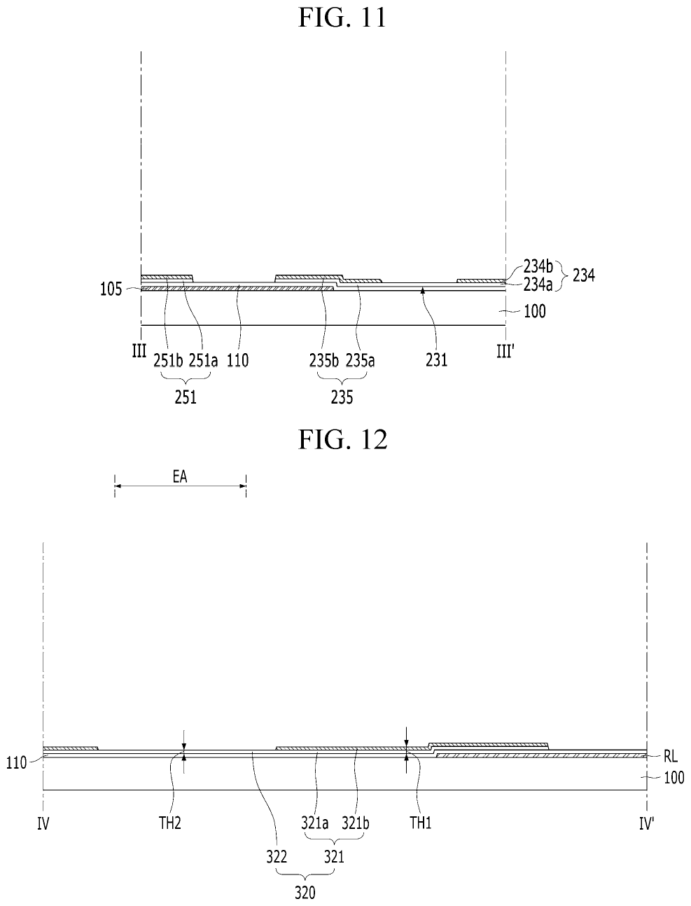

FIGS. 9 to 22 are views sequentially showing a method of forming the display apparatus according to the embodiment of the present disclosure.

The method of forming the display apparatus according to the embodiment of the present disclosure will be described with reference to FIGS. 7 to 22. First, the method of forming the display apparatus according to the embodiment of the present disclosure may include a step of forming a light-blocking pattern 105 and a reference voltage supply line RL on a device substrate 100, and a step of forming a buffer insulating layer 110 on the light-blocking pattern 105 and the reference voltage supply line RL, as shown in FIGS. 9 and 10.

The reference voltage supply line RL may be formed simultaneously with the light-blocking pattern 105. For example, the step of forming the light-blocking pattern 105 and the reference voltage supply line RL may include a step of forming a conductive material layer on the device substrate 100, and a step of patterning the conductive material layer. The conductive material layer may include a material having a relative low resistance. For example, the conductive material layer may be formed of a metal, such as aluminum (Al), chrome (Cr), copper (Cu), molybdenum (Mo), titanium (Ti) and tungsten (W).

The buffer insulating layer 110 may be formed of an insulating material. For example, the buffer insulating layer 110 may be formed of an inorganic insulating material, such as silicon oxide (SiO) and silicon nitride (SiN). An upper surface of the device substrate 110 toward the light-blocking pattern 105 and the reference voltage supply line RL may be completely covered by the buffer insulating layer 110. For example, a side of the light-blocking pattern 105 and a side of the reference voltage supply line RL may be covered by the buffer insulating layer 110.

A data line and a power voltage supply line may be formed on the device substrate 100. The data line and the power voltage supply line may be formed simultaneously with the reference voltage supply line RL. For example, the data line and the power voltage supply line may be formed between the device substrate 100 and the buffer insulating layer 110. The data line and the power voltage supply line may be spaced apart from the reference voltage supply line RL. For example, the data line and the power voltage supply line may be formed parallel to the reference voltage supply line RL.

The method of forming the display apparatus according to the embodiment of the present disclosure may include a step of forming a first conductive pattern 251, a third semiconductor pattern 231, a third source electrode 234, a third drain electrode 235 and a second connection wiring 320 on the buffer insulating layer 110.

The first conductive pattern 251 may be formed in a two-layer structure. For example, the first conductive pattern 251 may be formed in a stacked structure of a lower pattern layer 251a and an upper pattern layer 251b. The third source electrode 234 may be formed in a two-layer structure. For example, the third source electrode 234 may be formed in a stacked structure of a third source lower layer 234a and a third source upper layer 234b. The third drain electrode 235 may be formed in a two-layer structure. For example, the third drain electrode 235 may be formed in a stacked structure of a third drain lower layer 235a and a third drain upper layer 235b.

The second connection wiring 320 may include a second opaque wiring region 321 and a second transparent wiring region 322, which are disposed side by side. The second transparent wiring region 322 may overlap an emission area EA formed by a subsequent process. The second transparent wiring region 322 may have a transmittance higher than the second opaque wiring region 321. For example, a transmittance of the second transparent wiring region 322 may be higher than a transmittance of the reference voltage supply line RL. The second transparent wiring region 322 may be formed to have a thickness smaller than the second opaque wiring region 321. For example, the second opaque wiring region 321 may be formed in a stacked structure of a second lower wiring layer 321a and a second upper wiring layer 321b, and the second transparent wiring region 322 may be formed in a single-layer structure.

The first conductive pattern 251, the third semiconductor pattern 231, the third source electrode 234, the third drain electrode 235 and the second connection wiring 320 may be formed using a half-tone mask. For example, the step of forming the first conductive pattern 251, the third semiconductor pattern 231, the third source electrode 234, the third drain electrode 235 may include a step of forming an oxide semiconductor material layer on the buffer insulating layer 110, a step of forming a conductive material layer on the oxide semiconductor material layer, a step of arranging a half-tone mask overlapping with the first conductive pattern 251, the third semiconductor pattern 231, the third source electrode 234, the third drain electrode 235 and the second connection wiring 320 and having a relative large thickness on the upper pattern layer 251b, the third source upper layer 234b, the third drain upper layer 235b and the second upper wiring layer 321b, a step of sequentially etching the conductive material layer and the oxide semiconductor material layer using the half-tone mask, a step of forming a mask pattern overlapping the upper pattern layer 251b, the third source upper layer 234b, the third drain upper layer 235b and the second upper wiring layer 321b by removing a region of the half-tone mask having a relative small thickness, and a step of removing a portion of the conductive material layer exposed by the mask pattern. Thus, in the method of forming the display apparatus according to the embodiment of the present disclosure, the upper pattern layer 251b, the third source upper layer 234b, the third drain upper layer 235b and the second upper wiring layer 321b may be formed of a same material, and the lower pattern layer 251b, the third semiconductor pattern 231, the third source lower layer 234a, the third drain lower layer 235a and the second lower wiring layer 321a may be formed of a same material. The third semiconductor pattern 231 may be formed in a single-layer structure.

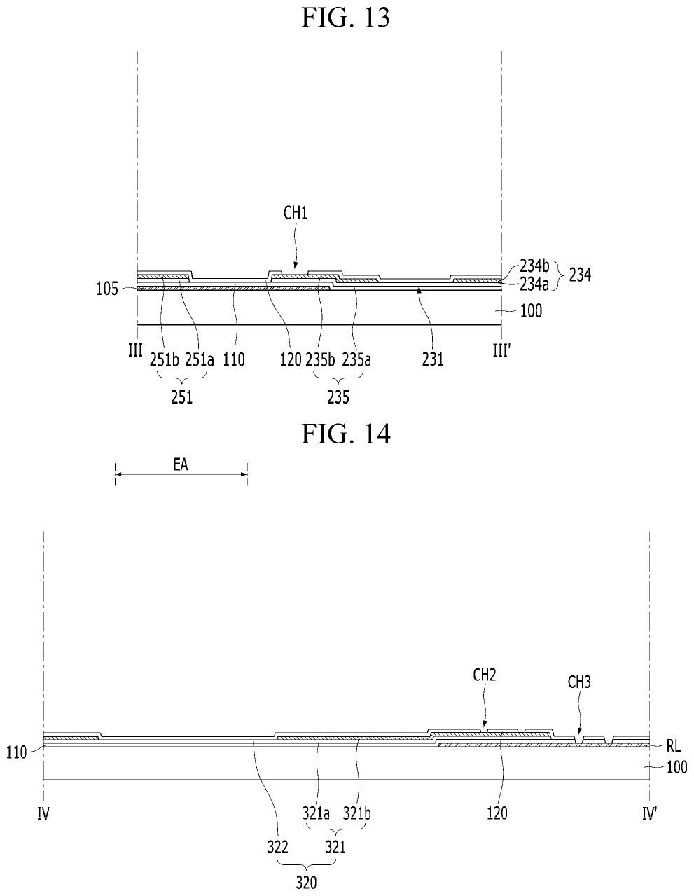

The method of forming the display apparatus according to the embodiment of the present disclosure may include a step of forming an interlayer insulating layer 120 on the device substrate 100 in which the first conductive pattern 251, the third semiconductor pattern 231, the third source electrode 234, the third drain electrode 235 and the second connection wiring 320, and a step of forming contact holes CH1, CH2 and CH3 in the interlayer insulating layer 120, as shown in FIGS. 13 and 14.

The interlayer insulating layer 120 may include an insulating material. For example, the interlayer insulating layer 120 may be formed of an inorganic insulating material, such as silicon oxide (SiO) and silicon nitride (SiN).

The contact holes CH1, CH2 and CH3 may include a first contact hole CH1 partially exposing an upper surface of the third drain upper layer 235b, a second contact hole CH2 partially exposing an upper surface of the second upper wiring layer 321b, and a third contact hole CH3 partially exposing an upper surface of the reference voltage supply line RL. The first contact hole CH1 and the second contact hole CH2 may penetrate the interlayer insulating layer 120. The third contact hole CH3 may penetrate the interlayer insulating layer 120 and the buffer insulating layer 110. Since the third drain upper layer 235b and the second upper wiring layer 321b are formed of a metal, a process of forming the third contact hole CH3 may be performed in a same process chamber as a process of forming the first contact hole CH1 and the second contact hole CH2. Thus, in the method of forming the display apparatus according to the embodiment of the present disclosure, process efficiency may be effectively improved.

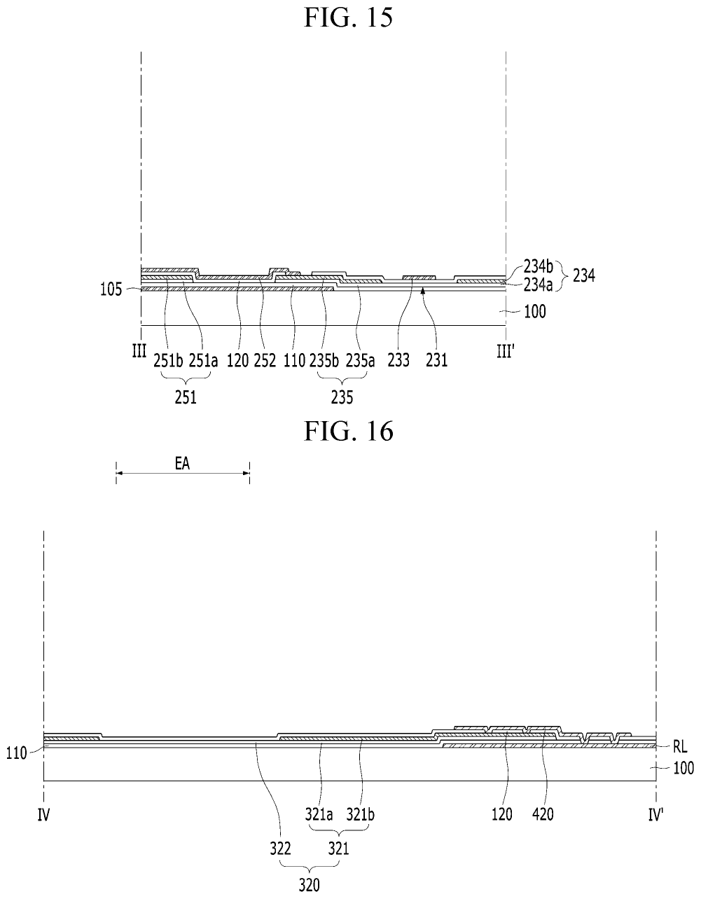

The method of forming the display apparatus according to the embodiment of the present disclosure may include a step of forming a second conductive pattern 252, a third gate electrode 233 and a second intermediate electrode 420 on the device substrate 100 in which the contact holes CH1, CH2 and CH3 are formed, as shown in FIGS. 15 and 16.

The second conductive pattern 252 may be formed on an upper surface of the first conductive pattern 251. An end of the second conductive pattern 252 may be formed in the first contact hole CH1. For example, the second conductive pattern 252 may be in direct contact with the third drain upper layer 235b in the first contact hole CH1. An end of the second conductive pattern 252 may partially cover a portion of the third drain upper layer 235b exposed by the first contact hole CH1.

The third gate electrode 233 may be formed on a portion of the third semiconductor pattern 231. For example, the third gate electrode 233 may be formed between the third source upper layer 234b and the third drain upper layer 235b. The third gate electrode 233 may be spaced apart from the third source upper layer 234b and the third drain upper layer 235b. For example, the third gate electrode 233 may be formed on a central region of the third semiconductor pattern 231.

The second intermediate electrode 420 may be formed on a portion of the second upper wiring layer 321b and a portion of the reference voltage supply line RL. For example, the second intermediate electrode 420 may be in direct contact with the second upper wiring layer 321b through the second contact hole CH2, and be in direct contact with the reference voltage supply line RL through the third contact hole CH3.

The second conductive pattern 252, the third gate electrode 233 and the second intermediate electrode 420 may be formed simultaneously. For example, the step of forming the second conductive pattern 252, the third gate electrode 233 and the second intermediate electrode 420 may include a conductive material layer on the interlayer insulating layer 120 in which the contact holes CH1, CH2 and CH3 are formed, and a step of patterning the conductive material layer. The second conductive pattern 252, the third gate electrode 233 and the second intermediate electrode 420 may be formed of a material having a relative low resistance. For example, the conductive material layer may be formed of a metal, such as aluminum (Al), chrome (Cr), copper (Cu), molybdenum (Mo), titanium (Ti) and tungsten (W).

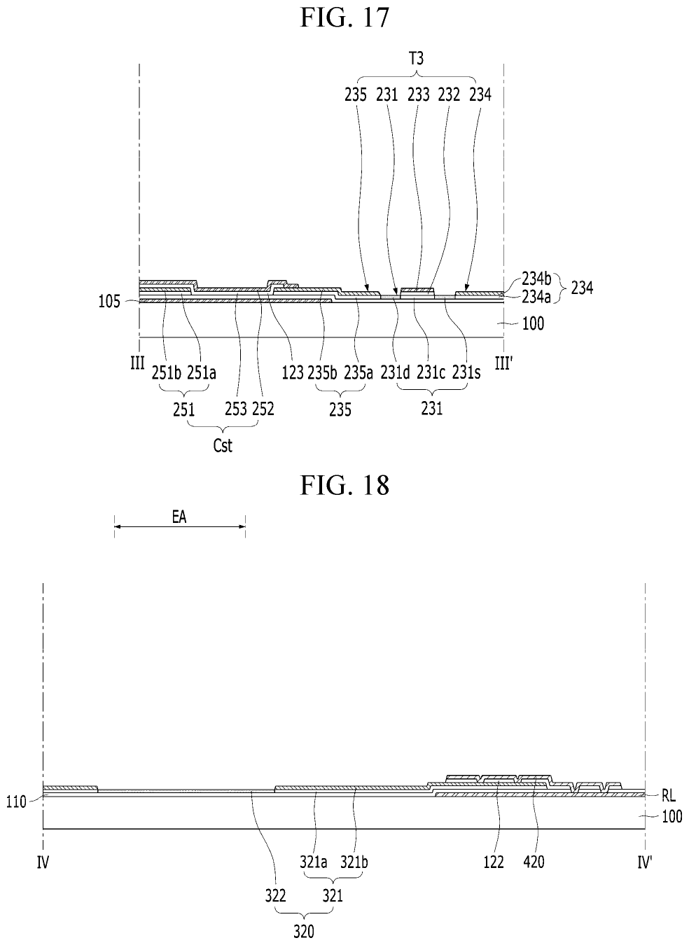

The method of forming the display apparatus according to the embodiment of the present disclosure may include a step of forming a capacitor insulating layer 253, a third gate insulating layer 232 and a second intermediate insulating layer 122 using the interlayer insulating layer 120, as shown in FIGS. 17 and 18.

The step of forming the capacitor insulating layer 253, the third gate insulating layer 232 and the second intermediate insulating layer 122 may include a step of pattering the interlayer insulating layer 120 using the second conductive pattern 252, the third gate electrode 233 and the second intermediate electrode 420 as an etch mask. For example, the capacitor insulating layer 253 may be formed under the second conductive pattern 252, the third gate insulating layer 232 may be formed under the third gate electrode 233, and the second intermediate insulating layer 122 may be formed under the second intermediate electrode 420. The first conductive pattern 251, the second conductive pattern 252 and the capacitor insulating layer 253 may constitute a storage capacitor Cst. The third semiconductor pattern 231, the third gate insulating layer 232, the third gate electrode 233, the third source electrode 234 and the third drain electrode 235 may constitute a third thin film transistor T3.

A portion of the third semiconductor pattern 231 and the second transparent wiring region 322 which are not covered by the third gate electrode 233, the third source upper layer 234b and the third drain upper layer 235b, the upper wiring layer 321b and the second intermediate electrode 420 may exposed to an etchant or an etching gas used in a process of patterning the interlayer insulating layer 120. For example, a portion of the third semiconductor pattern 231 between the third gate electrode 233 and the third source upper layer 234b, a portion of the third semiconductor pattern 231 between the third gate electrode 233 and the third drain upper layer 235b, and the second transparent wiring region 322 may be conductorized by the process of patterning the interlayer insulating layer 120.

A region conductorized by the process of patterning the interlayer insulating layer 120 may have a resistance lower than a region, which is not conductorized. For example, the portion of the third semiconductor pattern 231 between the third gate electrode 233 and the third source upper layer 234b may become a third source region 231s by the process of patterning the interlayer insulating layer 120, and the portion of the third semiconductor pattern 231 between the third gate electrode 233 and the third drain upper layer 235b may become a third drain region 231d by the process of patterning the interlayer insulating layer 120. The third source region 231s and the third drain region 231d may be formed outside the third gate insulating layer 232.

A portion of the third semiconductor pattern 231, which is not conductorized by the process of patterning the interlayer insulating layer 120 may become a third channel region 231c. For example, the third channel region 231c of the third semiconductor pattern 231 may overlap the third gate electrode 233. The third source lower layer 234a overlapping with the third source upper layer 234b, the third drain lower layer 235a overlapping with the third drain upper layer 235b, and the lower wiring layer 321a overlapping with the upper wiring layer 321b may be not conductorized by the process of patterning the interlayer insulating layer 120. For example, the third channel region 231c of the third semiconductor pattern 231, the third source lower layer 234a, the third drain lower layer 235a and the lower wiring layer 321a may be a region of an oxide semiconductor, which is not conductorized. The second transparent wiring region 322 may have a resistance lower than the second lower wiring layer 321a.

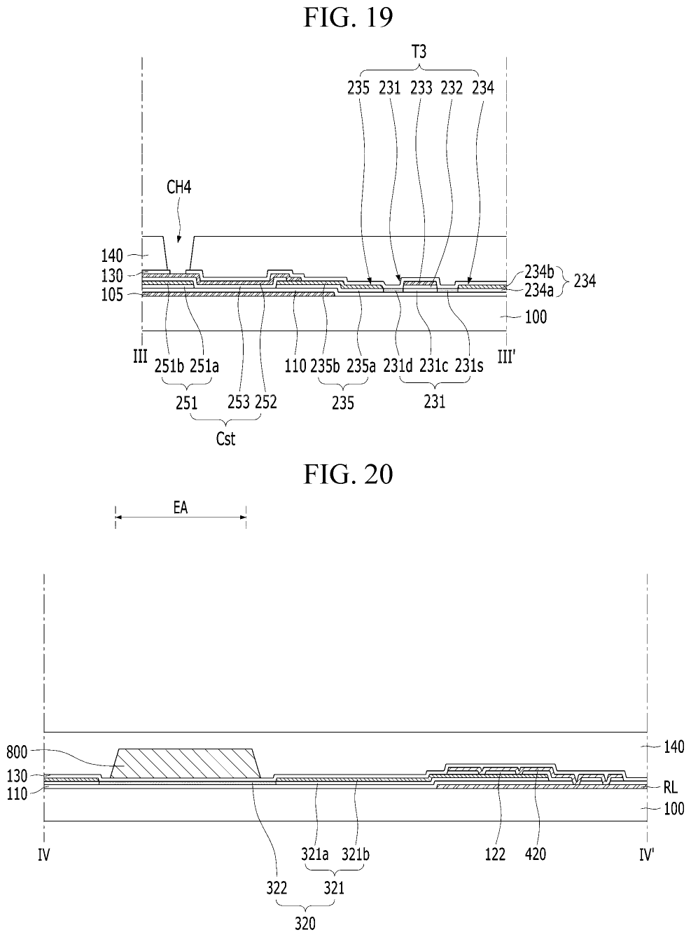

The method of forming the display apparatus according to the embodiment of the present disclosure may include a step of forming a lower passivation layer 130 on the device substrate 100 in which the storage capacitor Cst and the third thin film transistor T3 are formed, a step of forming a color filter 800 on the lower passivation layer 130, a step of forming an over-coat layer 140 covering the color filter 800, and a step of forming a fourth contact hole CH4 exposing a portion of the second conductive pattern 252 by penetrating the lower passivation layer 130 and the over-coat layer 140, as shown in FIGS. 19 and 20.

The lower passivation layer 130 and the over-coat layer 140 may be formed of an insulating material. The over-coat layer 140 may be formed of a material different from the lower passivation layer 130. For example, the lower passivation layer 130 may be formed of an inorganic insulating material, such as silicon oxide (SiO) and silicon nitride (SiNO, and the over-coat layer 140 may be formed of an organic insulating material.

The color filter 800 may be formed in the emission area EA defined by a subsequent process. For example, the color filter 800 may be formed on the second transparent wiring region 322.

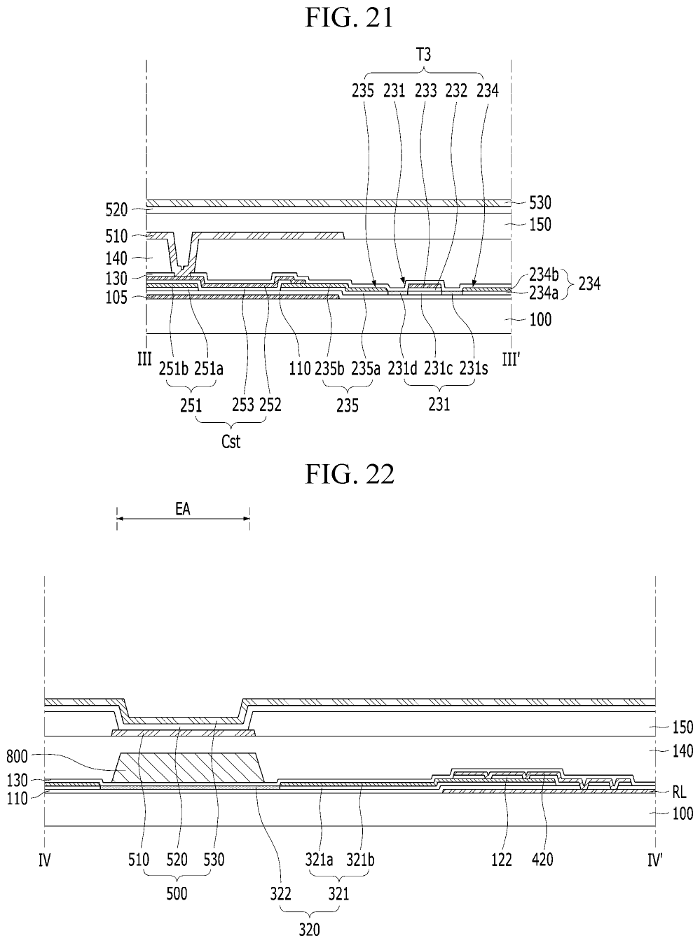

The method of forming the display apparatus according to the embodiment of the present disclosure may include a step of forming a light-emitting device 500 and a bank insulating layer 150 on the over-coat layer 140, as shown in FIGS. 21 and 22.

The bank insulating layer 150 may surround the emission area EA. For example, the bank insulating layer 150 may include an opening overlapping with the emission area EA. The bank insulating layer 150 may be formed of an insulating material. For example, the bank insulating layer 150 may be formed of an organic insulating material.

The light-emitting device 500 may be formed in the emission area EA. The light-emitting device 500 may be formed in a stacked structure of a first electrode 510, a light-emitting layer 520 and a second electrode 530. For example, the first electrode 510 of the light-emitting device 500 may be in direct contact with the second conductive pattern 252 through the fourth contact hole CH4. An edge of the first electrode 510 may be covered by the bank insulating layer 150. For example, the light-emitting layer 520 and the second electrode 530 may be formed on the device substrate 100 in which the bank insulating layer 150 is formed.

The method of forming the display apparatus according to the embodiment of the present disclosure may include a step of attaching an encapsulation substrate 700 on the device substrate 100 in which the light-emitting device 500 is formed, using an encapsulating element 600, as shown in FIGS. 7 and 8.

The encapsulating element 600 may include an insulating material. The encapsulating element 600 may have a relative low water vapor transmission rate. For example, the encapsulating element 600 may include an olefin-based material. The encapsulation substrate 700 may include a material having a specific strength or higher. The encapsulation substrate 700 may include a material having a relative high thermal-conductivity. For example, the encapsulation substrate 700 may include a metal, such as aluminum (Al), nickel (Ni) and iron (Fe).

Accordingly, the display apparatus according to the embodiment of the present disclosure may include the light-emitting device 500 and the driving circuit DC in each pixel area PX, wherein the light-emitting device 500 electrically connected to the driving circuit DC may be disposed in the emission area EA, wherein the driving circuit DC disposed outside the emission area EA may be electrically connected to the signal wirings DL, GL, PL and RL through the connection wirings 310 and 320, and wherein the transparent wiring region 312 and 322 of each connection wiring 310 and 320 having a relative high transmittance may overlap the first electrode 510 of one of the pixel areas PX. Thus, in the display apparatus according to the embodiment of the present disclosure, the light emitted from the light-emitting device 500 of each pixel area PX may be not blocked by the connection wirings 310 and 320. That is, in the display apparatus according to the embodiment of the present disclosure, the emission area EA of each pixel area PX may be increased, without affecting a repair process. Therefore, in the display apparatus according to the embodiment of the present disclosure, the luminance efficiency of each pixel area PX may be improved.

The display apparatus according to the embodiment of the present disclosure is described that the data driver DD, the gate driver GD, the timing controller TC and the power unit PU are disposed outside the display panel DC, the plurality of the pixel areas PX are disposed in a display area AA of the display panel DP, and the signal wirings DL, GL, PL and RL cross a bezel area BZ of the display panel DP disposed outside the display area AA. However, in the display apparatus according to another embodiment of the present disclosure, at least one of the data driver DD, the gate driver GD, the timing controller TC and the power unit PU may be formed on the bezel area BZ of the display panel DP. For example, the display apparatus according to another embodiment of the present disclosure may be a GIP (Gate In Panel) type display apparatus in which the gate driver GD is mounted on the bezel area BZ of the display panel DP.

The display apparatus according to the embodiment of the present disclosure is described that the first thin film transistor T1, the second thin film transistor T2 and the third thin film transistor T3 are simultaneously formed. However, in the display apparatus according to another embodiment of the present disclosure, the first semiconductor pattern of the first thin film transistor T1, the second semiconductor pattern 221 of the second thin film transistor T2 and the third semiconductor pattern 231 of the third thin film transistor T3 may be disposed on layers different from each other. For example, in the display apparatus according to another embodiment of the present disclosure, the third semiconductor pattern 231 of the third thin film transistor T3 may include a material different from the second semiconductor pattern 221 of the second thin film transistor T2. The third semiconductor pattern 231 of the third thin film transistor T3 may have characteristics different from the second semiconductor pattern 221 of the second thin film transistor T2. For example, the third semiconductor pattern 231 of the third thin film transistor T3 may be formed of a low-temperature Poly-Si (LTPS), and the second semiconductor pattern 221 of the second thin film transistor T2 may be formed of an oxide semiconductor. Thus, in the display apparatus according to another embodiment of the present disclosure, a decree of freedom for the configuration of the driving circuit DC in each pixel PX may be improved.

The display apparatus according to the embodiment of the present disclosure is described that the third thin film transistor T3 is turn on/off simultaneously with the first thin film transistor T1. However, in the display apparatus according to another embodiment of the present disclosure, the third thin film transistor T3 may be controlled from the first thin film transistor T1, independently. For example, in the display apparatus according to another embodiment of the present disclosure, the signal wirings GL, DL, PL and RL may include a reset wiring sequentially applying a reset signal to the third gate electrode 233 of the third thin film transistor T3 in each pixel area PX. Thus, in the display apparatus according to another embodiment of the present disclosure, a degree of freedom for the arrangement of the driving circuit DC in each pixel area PX may be improved.

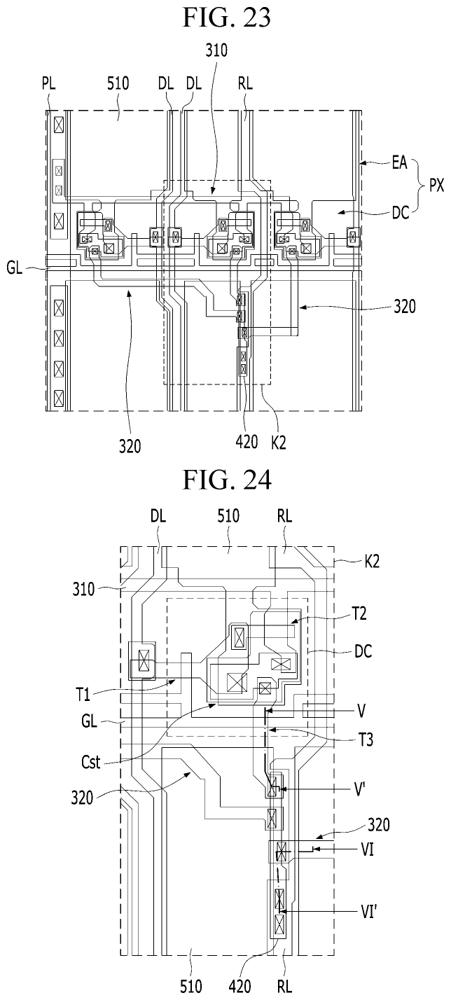

The display apparatus according to the embodiment of the present disclosure is described that the source electrode 224 and 234 and the drain electrode 225 and 235 of each thin film transistor T1, T2 and T3 have a stacked structure of a lower layer 224a, 225a, 234a and 235a and an upper layer 224b, 225b, 234b and 235b. However, in the display apparatus according to another embodiment of the present disclosure, the source electrode 224 and 234 and the drain electrode 225 and 235 of each thin film transistor T1, T2 and T3 may be formed in various shapes. For example, in the display apparatus according to another embodiment of the present disclosure, the third source electrode 234 and the third drain electrode 235 of the third thin film transistor T3 may have a single-layer structure, as shown in FIGS. 23 to 25.

The third source electrode 234 and the third drain electrode 235 may be disposed on a same layer as the third semiconductor pattern 231. For example, the third source electrode 234 and the third drain electrode 235 may include a same material as the third semiconductor pattern 231. The third source electrode 234 and the third drain electrode 235 may have a resistance lower than the third channel region of the third semiconductor pattern 231. For example, the third source electrode 234 and the third drain electrode 235 may be a conductorized region of an oxide semiconductor. The third source electrode 234 may be in direct contact with the third source region of the third semiconductor pattern 231, and the third drain electrode 235 may be in direct contact with the third drain region of the third semiconductor pattern 231. The third source electrode 234 may have a same resistance as the third source region of the third semiconductor pattern 231, and the third drain electrode 235 may have a same resistance as the third drain region of the third semiconductor pattern 231. For example, the third source electrode 234 and the third drain electrode 235 may be formed simultaneously with the third source region and the third drain region of the third semiconductor pattern 231. The third source electrode 234 and the third drain electrode 235 may be physically connected to the third semiconductor pattern 231. For example, the third source electrode 234 and the third drain electrode 235 may be viewed as a single pattern with the third semiconductor pattern 231.

The display apparatus according to the embodiment of the present disclosure is described that the reference voltage supply line RL is electrically connected to the second opaque wiring region 321 of the second connection wiring 320 by the second intermediate electrode 420. However, in the display apparatus according to another embodiment of the present disclosure, the second intermediate electrode 420 may be electrically connected to the second transparent wiring region 322 of the second connection wiring 320. For example, in the display apparatus according to another embodiment of the present disclosure, the second connection wiring 320 connecting between the third thin film transistor T3 of each pixel area PX and the reference voltage supply line RL may be a transparent wiring having a single-layer structure, as shown in FIGS. 23 to 26. For example, the second connection wiring 320 may include a first transparent region 320a and a second transparent region 320b, which are disposed side by side on the buffer insulating layer 110.

The second transparent region 320b may be in direct contact with the first transparent region 320a. For example, a side of the second transparent region 320b may be physically connected to a side of the first transparent region 320a. The second transparent region 320b may be viewed as a single pattern with the first transparent region 320a.

The second transparent region 320b may include a same material as the first transparent region 320a. For example, the first transparent region 320a and the second transparent region 320b may include an oxide semiconductor, such as IGZO. The first transparent region 320a and the second transparent region 320b may include a same material as the third semiconductor pattern 231. For example, the second connection wiring 320 may be formed simultaneously with the third semiconductor pattern 231.

A resistance of the first transparent region 320a may be lower than a resistance of the second transparent region 320b. For example, the first transparent region 320a may be a conductorized region of an oxide semiconductor, and the second transparent region 320b may be a region of an oxide semiconductor, which is not conductorized. The second intermediate electrode 420 may be electrically connected to the third source electrode 234 by the first transparent region 320a. For example, the first transparent region 320a may be in direct contact with the third source electrode 234. A side of the first transparent region 320a may be physically connected to the third source region 234. For example, the first transparent region 320a may be viewed as a single pattern with the third source electrode 234. An end of the second intermediate electrode 420 may be in direct contact with an upper surface of the first transparent region 320a opposite to the device substrate 100. The second transparent region 320b may be not arranged between the second intermediate electrode 420 and the third source electrode 234. For example, the second transparent region 320b may overlap the second intermediate insulating layer 122.

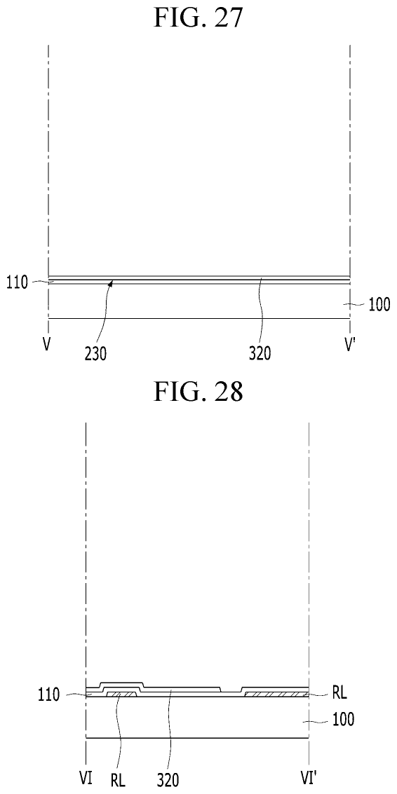

FIGS. 27 to 34 are views sequentially showing a method of forming the display apparatus according to another embodiment of the present disclosure.

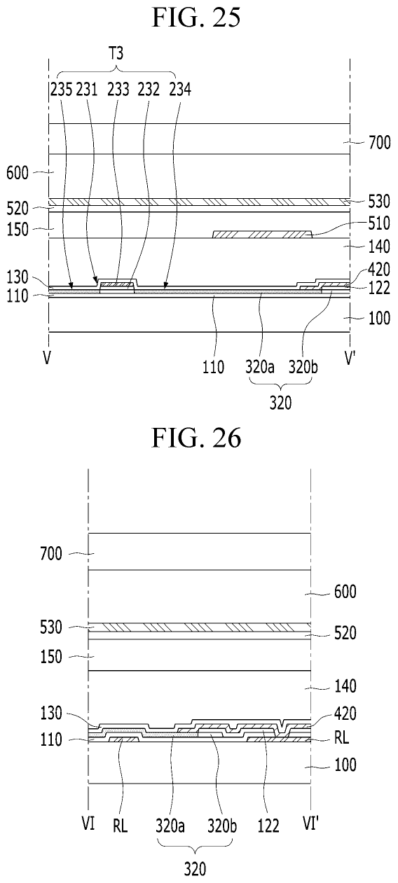

The method of forming the display apparatus according to another embodiment of the present disclosure will be described with reference to FIGS. 25 to 34. First, the method of forming the display apparatus according to another embodiment may include a step of forming a preliminary pattern 230 and a second connection wiring 320 on a device substrate 100 in which a buffer insulating layer 110 covering a reference voltage supply line RL is formed, as shown in FIGS. 27 and 28.

The preliminary pattern 230 may be formed of a semiconductor. For example, the preliminary pattern 230 may be formed of an oxide semiconductor, such as IGZO. The preliminary pattern 230 may be formed to overlap a region in which a third semiconductor pattern 231, a third source electrode 234 and a third drain electrode 235 are formed by a subsequent process.

The second connection wiring 320 may be formed in a single-layer structure. The second connection wiring 320 may be formed of a material having a transmittance higher than the reference voltage supply line RL. For example, the second connection wiring 320 may be formed of an oxide semiconductor, such as IGZO. The second connection wiring 320 may be formed simultaneously with the preliminary pattern 230. For example, the step of forming the preliminary pattern 230 and the second connection wiring 320 may include a step of forming an oxide semiconductor material layer on the buffer insulating layer 110, a step of arranging a mask pattern overlapping with the preliminary pattern 230 and the second connection wiring 320 on the oxide semiconductor material layer, and a step of patterning the oxide semiconductor material layer using the mask pattern. Thus, in the method of forming the display apparatus according to another embodiment of the present disclosure, the preliminary pattern 230 and the second connection wiring 320 may be formed in a single-layer structure made of an oxide semiconductor.

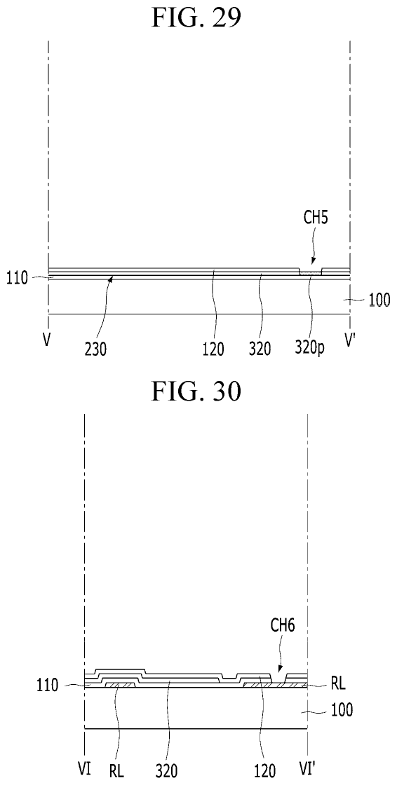

The method of forming the display apparatus according to the embodiment of the present disclosure may include a step of forming an interlayer insulating layer 120 on the device substrate 100 in which the preliminary pattern 230 and the second connection wiring 320 are formed, and a step of forming a fifth contact hole CH5 exposing a preliminary region 320p of the second connection wiring 320 and a sixth contact hole CH6 exposing a portion of the reference voltage supply line RL on the device substrate 100 in which the interlayer insulating layer 120 is formed, as shown in FIGS. 29 and 30.

The fifth contact hole CH5 may penetrate the interlayer insulating layer 120. For example, the preliminary region 320p of the second connection wiring 320 may overlap the fifth contact hole CH5. The preliminary region 320p of the second connection wiring 320 may be conductorized by a process of forming the fifth contact hole CH5. For example, the preliminary region 320p of the second connection wiring 320 may be conductorized by an etchant or an etching gas used in the process of forming the fifth contact hole CH5. The sixth contact hole CH6 may penetrate the interlayer insulating layer 120 and the buffer insulating layer 110.

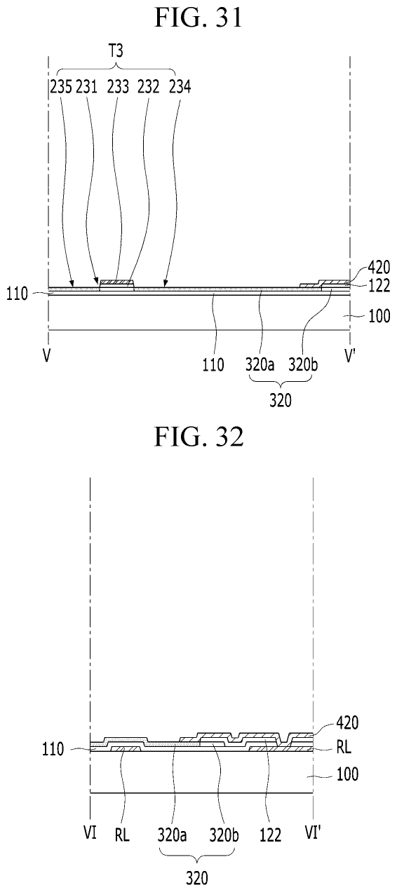

The method of forming the display apparatus according to the embodiment of the present disclosure may include a step of forming a third gate electrode 233 and a second intermediate electrode 420 on the interlayer insulating layer 120, and a step of forming a third gate insulating layer 232 and the second intermediate insulating layer 122 using the third gate electrode 233 and the second intermediate electrode 420, as shown in FIGS. 31 and 32.

The third gate electrode 233 may be formed on a portion of the preliminary pattern 230. For example, the third gate electrode 233 may be formed to overlap a region in which a third channel region is formed by a subsequent process.

The second intermediate electrode 420 may be in direct contact with the preliminary region 320p of the second connection wiring 320 through the fifth contact hole CH5, and be in direct contact with the reference voltage supply line RL through the sixth contact hole CH6. For example, the reference voltage supply line RL may be electrically connected to the preliminary region 320p of the second connection wiring 320 through the second intermediate electrode 420.

An end of the second intermediate electrode 420 may be formed in the fifth contact hole CH5. For example, an end of the second intermediate electrode 420 may partially cover an upper surface of the preliminary region 320p exposed by the fifth contact hole CH5. An end of the second intermediate electrode 420 may be in direct contact with the upper surface of the preliminary region 320p in the fifth contact hole CH5.

The second intermediate electrode 420 may be formed of a same material as the third gate electrode 233. The second intermediate electrode 420 may be formed simultaneously with the third gate electrode 233. For example, the step of forming the third gate electrode 233 and the second intermediate electrode 420 may include a step of forming a conductive material layer on the interlayer insulating layer 120 of the device substrate 100 in which the fifth contact hole CH5 and the sixth contact hole CH6 are formed, and a step of patterning the conductive material layer. The conductive material layer may be formed of a material having a relative low resistance. For example, the conductive material layer may be formed of a metal, such as aluminum (Al), chrome (Cr), copper (Cu), molybdenum (Mo), titanium (Ti) and tungsten (W).

The third gate insulating layer 232 may be formed under the third gate electrode 233. The second intermediate insulating layer 122 may be formed under the second intermediate electrode 420. The second intermediate insulating layer 122 may be formed simultaneously with the third gate insulating layer 232. For example, the step of forming the third gate insulating layer 232 and the second intermediate insulating layer 122 may include a step of pattering the interlayer insulating layer 122 using the third gate electrode 233 and the second intermediate electrode 420. The second intermediate insulating layer 122 may be formed of a same material as the third gate insulating layer 232.

A portion of the preliminary pattern 230 disposed outside the third gate electrode 233 may be exposed to an etchant or an etching gas used in a process of patterning the interlayer insulating layer 120. For example, a portion of the preliminary pattern 230 disposed outside the third gate electrode 233 may be conductorized by an etchant or an etching gas used in a process of patterning the interlayer insulating layer 120. A conductorized portion of the preliminary region 230 may become a third source region, a third drain region, the third source electrode 234 and the third drain electrode 235. A portion of the preliminary pattern 230 overlapping with the third gate electrode 233 may be not conductorized. For example, a portion of the preliminary pattern 230 overlapping with the third gate electrode 233 may become the third channel region. The third source region, the third drain region and the third channel region may constitute a third semiconductor pattern 231. The third semiconductor pattern 231 may be formed between the third source electrode 234 and the third drain electrode 235. For example, the third source region may be formed between the third source electrode 234 and the third channel region, and the third drain region may be formed between the third channel region and the third drain electrode 235. The third semiconductor 231, the third gate insulating layer 232, the third gate electrode 233, the third source electrode 234 and the third drain electrode 235 may constitute a third thin film transistor T3.

A portion of the second connection wiring 320 disposed outside the second intermediate electrode 420 may be conductorized by a process of patterning the interlayer insulating layer 120. A portion of the second connection wiring 320 conductorized by the process of patterning the interlayer insulating layer 120 may be physically connected to the preliminary region 320p of the second connection wiring 320. For example, the second connection wiring 320 may include a first transparent region 320a which is a conductorized region of an oxide semiconductor, and a second transparent region 320b which is a region of an oxide semiconductor, which is not conductorized. The first transparent region 320a may include a region disposed between the third source region 234 and the second intermediate electrode 420, and a region directly contacting an end of the second intermediate electrode 420. The second transparent region 320b may overlap the second intermediate insulating layer 320b. A boundary surface between the first transparent region 320a and the second transparent region 320b may be vertically aligned with a side of the second intermediate insulating layer 122. A side of the third source electrode 234 may be in direct contact with a side of the first transparent region 320a.

The method of forming the display apparatus according to the embodiment of the present disclosure may include a step of forming a lower passivation layer 130 on the third thin film transistor T3, the second intermediate electrode 420 and the second connection wiring 320, a step of forming an over-coat layer 140 on the lower passivation layer 130, a step of forming a first electrode 510, a bank insulating layer 150, a light-emitting layer 520 and a second electrode 530 on the over-coat layer 140, and a step of attaching an encapsulation substrate 700 on the device substrate 100 in which the second electrode 530 is formed using an encapsulating element 600, as shown in FIGS. 25 and 26.

That is, the display apparatus according to another embodiment of the present disclosure may include the second connection wiring 320 connecting between the third source electrode 234 of the third thin film transistor T3 and the reference voltage supply line RL, wherein the second connection wiring 320 may have a single-layer structure formed by the first transparent region 320a and the second transparent region 320b, which are disposed side by side, and wherein the first transparent region 320a of the second connection wiring 320 being in direct contact with the third source lower layer 234a of the third source electrode 234 and the second intermediate electrode 420 electrically connected to the reference voltage supply line RL may be a conductorized region of an oxide semiconductor. Thus, in the display apparatus according to another embodiment of the present disclosure, an area reduce of the emission area due to the second connection wiring 320 may be prevented, without adding a process for electrically connecting between the third source electrode 234 and the reference voltage supply line RL. Therefore, in the display apparatus according to another embodiment of the present disclosure, a decrease in the luminance efficiency may be prevented, without a decrease in the process efficiency.

And, in the display apparatus according to another embodiment of the present disclosure, the third source electrode 234 and the third drain electrode 235 may be formed simultaneously with the third source region and the third drain region of the third semiconductor pattern 231. Thus, in the display apparatus according to another embodiment of the present disclosure, the process efficiency may be improved.

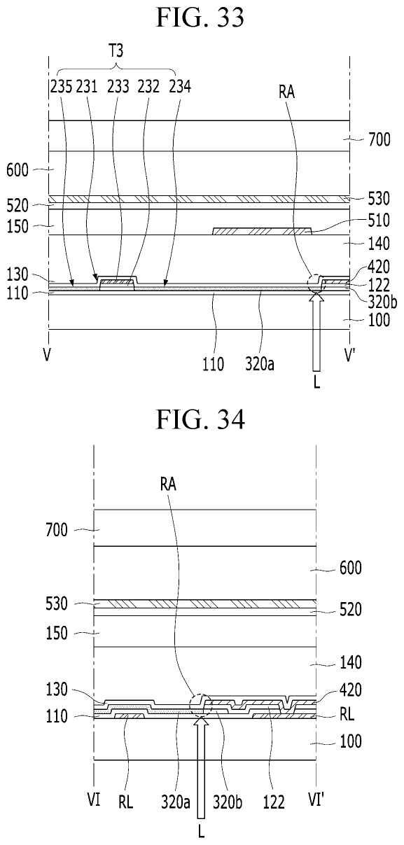

In the display apparatus according to another embodiment of the present disclosure, the reference voltage supply line RL may bypass a portion of the second intermediate electrode 420 contacting the first transparent region 320a, as shown in FIGS. 23 and 24. For example, an end of the second intermediate electrode 420 contacting the first transparent region 320a may not overlap the reference voltage supply line RL. Thus, in the display apparatus according another embodiment of the present disclosure, a laser L for a repair process may irradiate a contact area RA of the first transparent region 320a and the second intermediate electrode 420 passing through the device substrate 100, as shown in FIGS. 33 and 34. That is, in the display apparatus according to another embodiment of the present disclosure, an end of the second intermediate electrode 420 contacting the first transparent region 320a may be removed by the laser L irradiated for the repair process. Therefore, in the display apparatus according to another embodiment of the present disclosure, the second connection wiring 320 may be electrically separated from the second intermediate electrode 420 by the irradiation of the laser L for the repair process. Accordingly, in the display apparatus according to another embodiment of the present disclosure, a decrease in the process efficiency and a decrease in the luminance efficiency may be prevented, without affecting the repair process.

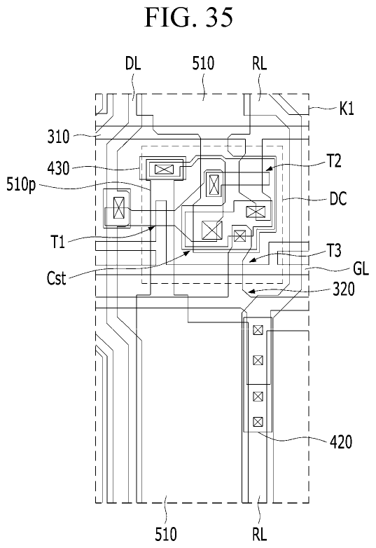

In the display apparatus according to another embodiment of the present disclosure, the first electrode 510 electrically separated from the driving circuit DC may be electrically connected to the driving circuit DC of adjacent pixel area PX by the repair process. For example, in the display apparatus according to another embodiment of the present disclosure, each of the first electrodes 510 may include a protruding region 510p extending onto adjacent driving circuit DC, as shown in FIG. 35. The protruding region 510p may include a region overlapping with a third intermediate electrode 430, which is electrically connected to adjacent driving circuit DC. For example, the protruding region 510p and the third intermediate electrode 430 may be melted/coupled by the irradiation of laser. Thus, in the display apparatus according to another embodiment of the present disclosure, generation of dark spot due to the repair process may be prevented. Therefore, in the display apparatus according to another embodiment of the present disclosure, a decrease in the luminance efficiency may be effectively prevented.

In the result, the display apparatus according to the embodiments of the present disclosure may comprise the light-emitting device and the driving circuit in each pixel area, wherein the light-emitting device may be disposed on the emission area, wherein the driving circuit disposed outside the emission area may be electrically connected to the signal wiring through the connection wiring, wherein the connection wiring may include a transparent wiring region having a relative high transmittance, and wherein the transparent wiring region of the connection wiring may overlap the emission area. Thus, in the display apparatus according to the embodiments of the present disclosure, an area of the emission area in each pixel may be increased by the connection wiring. Thereby, in the display apparatus according to embodiments of the present disclosure, the luminance efficiency of each pixel area may be improved.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a light-emitting device on an emission area of a device substrate;
a driving circuit electrically connected to the light-emitting device, the driving circuit disposed outside the emission area;
a signal wiring disposed outside the light-emitting device and the emission area; and
a connection wiring electrically connected between the driving circuit and the signal wiring,
wherein the connection wiring includes a first wiring region and a second wiring region having a transmittance higher than the first wiring region, and
wherein the second wiring region of the connection wiring overlaps the emission area.

2. The display apparatus according to claim 1, further comprising a color filter between the second wiring region of the connection wiring and the light-emitting device.

3. The display apparatus according to claim 1, wherein the first wiring region has a resistance lower than the second wiring region.

4. The display apparatus according to claim 3, wherein a thickness of the second wiring region is smaller than a thickness of the first wiring region.

5. The display apparatus according to claim 3, wherein the first wiring region includes a lower wiring layer and an upper wiring layer on the lower wiring layer,
wherein a resistance of the upper wiring layer is smaller than a resistance of the lower wiring layer, and
wherein the second wiring region includes a same material as the lower wiring layer.

6. The display apparatus according to claim 5, wherein the upper wiring layer includes a metal material.

7. The display apparatus according to claim 5, wherein the second wiring region has a resistance lower than the lower wiring layer.

8. The display apparatus according to claim 7, wherein the lower wiring layer is a region of an oxide semiconductor, which is not conductorized, and
wherein the second wiring region is a conductorized region of the oxide semiconductor.

9. The display apparatus according to claim 5, wherein a thickness of the second wiring region is same as a thickness of the lower wiring layer.

10. A display apparatus, comprising:
a bank insulating layer on a device substrate, the bank insulating layer adjacent to an emission area in a pixel area of the device substrate;
a light-emitting device includes a first electrode, a light-emitting layer and a second electrode stacked on one another and overlapping the emission area of the pixel area;
a driving circuit between the pixel area of the device substrate and the bank insulating layer, the driving circuit including at least one thin film transistor; and
a signal wiring disposed outside the pixel area, the signal wiring electrically connected to the driving circuit by a connection wiring,
wherein the connection wiring includes a transparent wiring region overlapping with the first electrode, and
wherein a transmittance of the transparent wiring region is higher than a transmittance of the signal wiring.

11. The display apparatus according to claim 10, further comprising:
an intermediate insulating layer on the connection wiring and the signal wiring; and
an intermediate electrode on the intermediate insulating layer, the intermediate electrode electrically connected to the transparent wiring region of the connection wiring and the signal wiring,
wherein the intermediate electrode partially overlaps an upper surface of the transparent wiring region opposite to the device substrate.

12. The display apparatus according to claim 10, wherein the transparent wiring region of the connection wiring includes a same material as a semiconductor pattern of the thin film transistor.

13. The display apparatus according to claim 12, wherein the transparent wiring region of the connection wiring has a same resistance as at least one of a source region or a drain region of the semiconductor pattern.

14. The display apparatus according to claim 12, wherein a source electrode and a drain electrode of the thin film transistor each includes a lower conductive layer and an upper conductive layer on the lower conductive layer,
wherein a resistance of the upper conductive layer is lower than a resistance of the lower conductive layer, and
wherein the lower conductive layer includes a same material as the semiconductor pattern.

15. The display apparatus according to claim 14, wherein the lower conductive layer has a same resistance as a channel region of the semiconductor pattern.

16. The display apparatus according to claim 14, wherein the upper conductive layer includes a material different from a gate electrode of the thin film transistor.

17. A display apparatus comprising:
a light-emitting device including a light emission area;
a driving circuit electrically connected to the light-emitting device; and
a connection wiring electrically connected to the driving circuit, the connection wiring including a first layer in contact with the driving circuit and a second layer on the first layer and spaced apart from the driving circuit.

18. The display apparatus of claim 17, wherein at least a portion of the first layer is transparent and the second layer is opaque.

19. The display apparatus of claim 17, wherein the first layer includes a semiconductor material, and the second layer includes a metal material.

20. The display apparatus of claim 17, wherein the first layer includes a first portion and a second portion, the second portion overlapping with the second layer and positioned further away from the driving circuit than the first portion, the first portion and the second portion having respective electrical conductivity properties different from one another.

21. The display apparatus of claim 17, wherein the driving circuit includes a driving transistor having a semiconductor region in a same layer as the first layer of the connection wiring.
